(19) United States
(12) Patent Application Publication
(10) Pub. No.: US 2024/0036117 A1
(43) Pub. Date: Feb. 1, 2024

(54) BATTERY EVALUATION SYSTEM, BATTERY EVALUATION METHOD, PROGRAM, AND RECORDING MEDIUM

(71) Applicant: SEMICONDUCTOR ENERGY LABORATORY CO., LTD., Atsugi-shi (JP)

(72) Inventors: Kazuki TANEMURA, Isehara (JP); Mayumi MIKAMI, Atsugi (JP); Kazuki HIGASHI, Atsugi (JP); Haruki KATAGIRI, Atsugi (JP); Kyoichi MUKAO, Odawara (JP)

(21) Appl. No.: 18/359,999

(22) Filed: Jul. 27, 2023

(30) Foreign Application Priority Data
Jul. 29, 2022 (JP) 2022-121332

(51) Int. Cl. G01R 31/3835; G01R 31/36

(52) U.S. Cl. CPC G01R 31/3835; G01R 31/3646; G01R 31/3648

(57) ABSTRACT

A battery evaluation system that performs evaluation by easily linking a plurality of measurement methods relating to a secondary battery is provided. A charge and discharge device is configured to perform, in a first period, either or both of charge and discharge of a secondary battery. The first measurement device is configured to perform, in the first period, measurement of a spectrum a plurality of times. The arithmetic portion is configured to generate a first graph using the plurality of measured spectra. The arithmetic portion is configured to generate data of a second graph using a set of data including a voltage and the time of measurement of the voltage. A display portion is configured to display the first graph and the second graph at the same time. The battery evaluation system is configured to set a first area in one of the first graph and the second graph and to display a second area corresponding to the first area in the other of the first graph and the second graph.

### BACKGROUND OF THE INVENTION

### 1. Field of the Invention

One embodiment of the present invention relates to a battery evaluation system, a battery evaluation method, a material search method, a material search system, a program, and a recording medium. One embodiment of the present invention relates to a method for evaluating a secondary battery and a method for measuring a secondary battery.

Note that one embodiment of the present invention is not limited to the above technical field. The technical field of the invention disclosed in this specification and the like relates to an object, a method, or a manufacturing method. One embodiment of the present invention relates to a process, a machine, manufacture, or a composition of matter.

### 2. Description of the Related Art

In recent years, various materials such as an inorganic material and an organic material have been actively developed in various technical fields. As a method for evaluating material's characteristics, an analysis method using an X-ray diffraction (XRD) method (also referred to as “XRD analysis”) is known. Examples of the XRD analysis include a powder X-ray diffraction method, and the XRD analysis can nondestructively evaluate crystallinity and orientation, or identify or estimate a material, for example. In particular, a powder X-ray diffraction method is widely used as a method for analyzing a polycrystalline substance.

In the XRD analysis, a sample is irradiated with a fixed-wavelength X-ray with varying incident angles, and the intensity of the reflected X-ray is measured to obtain a diffraction pattern inherent in the substance of the sample (also referred to as “2θ/θ measurement”, “2θ/ω measurement”, or “out-of-plane measurement”). From the obtained diffraction pattern (also referred to as “XRD profile”, “XRD spectrum”, or “powder plane”), elements constituting the sample, crystallinity, orientation, and the like can be found.

In recent years, a variety of power storage devices, such as lithium-ion secondary batteries, lithium-ion capacitors, and air batteries, have been actively developed. In particular, demand for lithium-ion secondary batteries with high output and high energy density has rapidly grown with the development of the semiconductor industry, for portable information terminals such as mobile phones, smartphones, tablets, and laptop computers; portable music players; digital cameras; medical equipment; next-generation clean energy vehicles such as hybrid electric vehicles (HEV), electric vehicles (EV), and plug-in hybrid electric vehicles (PHEV); and the like. The lithium-ion secondary batteries are essential as rechargeable energy supply sources for today's information society.

The performance required for lithium-ion secondary batteries includes higher energy density, improved cycling performance, safe operation under a variety of environments, and longer-term reliability, for example.

XRD analysis is one of methods used for analysis of a crystal structure of a positive electrode active material of a lithium-ion secondary battery.

XRD data can be analyzed with the use of crystal structure data stored in the Inorganic Crystal Structure Database (ICSD) introduced in Non-Patent Document 1. For example, the ICSD can be referred to for the lattice constant of the lithium cobalt oxide described in Non-Patent Document 2.

### REFERENCE

### Non-Patent Document

[Non-Patent Document 1] Belsky, A. et al., “New developments in the Inorganic Crystal Structure Database (ICSD): accessibility in support of materials research and design”, Acta Cryst., (2002), B58, 364-369.
[Non-Patent Document 2] Akimoto, J.; Gotoh, Y.; Oosawa, Y. “Synthesis and structure refinement of LiCoO₂ single crystals”, Journal of Solid State Chemistry (1998) 141, pp. 298-302.

### SUMMARY OF THE INVENTION

An object of one embodiment of the present invention is to provide an excellent method for evaluating a secondary battery. Another object of one embodiment of the present invention is to provide an excellent system for evaluating a secondary battery. Another object of one embodiment of the present invention is to provide a method for easily linking a plurality of measurement methods relating to a secondary battery. Another object of one embodiment of the present invention is to provide a system that performs evaluation by easily linking a plurality of measurement methods relating to a secondary battery. Another object of one embodiment of the present invention is to provide a method for dynamically linking a plurality of measurement methods relating to a secondary battery. Another object of one embodiment of the present invention is to provide a system that performs evaluation by dynamically linking a plurality of measurement methods relating to a secondary battery. Another object of one embodiment of the present invention is to provide a novel evaluation method. Another object of one embodiment of the present invention is to provide a novel evaluation system.

Note that the description of these objects does not preclude the existence of other objects. In one embodiment of the present invention, there is no need to achieve all these objects. Other objects will be apparent from and can be derived from the description of the specification, the drawings, the claims, and the like.

One embodiment of the present invention is a battery evaluation system including a charge and discharge device, a first measurement device, and an information processing device. The information processing device includes an arithmetic portion, a signal input/output portion, and a display portion. The signal input/output portion is configured to supply a signal to each of the charge and discharge device and the first measurement device. The charge and discharge device is configured to perform, in a first period, either or both of charge of a secondary battery and discharge of the secondary battery on the basis of the signal supplied from the signal input/output portion. The charge and discharge device is configured to measure a voltage of the secondary battery. The first measurement device is configured to perform, in the first period, measurement of a waveform such as a spectrum a plurality of times on the basis of the signal supplied from the signal input/output portion. The waveform such as the spectrum obtained by the measurement includes information derived from a material included in the secondary battery. The arithmetic portion is configured to generate a first graph using the plurality of measured waveforms such as the spectra. The arithmetic portion is configured to generate data of a second graph using a set of data including the voltage and time at which the voltage has been measured. The display portion is configured to display the first graph and the second graph at the same time. The battery evaluation system is configured to set a first area in one of the first graph and the second graph and to display a second area corresponding to the first area in the other of the first graph and the second graph.

In the above-described structure, it is preferable that the waveform such as the spectrum be one selected from an X-ray diffraction spectrum, a Raman spectrum, an infrared spectrum, a XANES spectrum, an XPS spectrum, neutron diffraction data, data containing positional information observed with a laser microscope, and data containing positional information observed with an SSRM and that the spectrum obtained by the spectrum measurement have a peak derived from the material included in the secondary battery.

In the above-described structure, the time at which the voltage has been measured and time at which the plurality of waveforms such as the spectra has been measured are preferably synchronized by a clock built in the information processing device.

In the above-described structure, it is preferable that an input device be further included and that the first area be set by data received from the input device.

In the above-described structure, the second area preferably corresponds to an area of time at which measurement of the first area has been conducted.

In the above-described structure, it is preferable that the measurement of the waveform such as the spectrum be X-ray diffraction spectrum measurement; that the first graph be a graph with a first variable on an x-axis, a second variable on a y-axis, and a third variable shown by color gradation of points on an xy plane; that the x-axis and the y-axis be orthogonal to each other in the first graph; that, in the first graph, an X-ray diffraction spectrum be shown using a relation between the first variable and the third variable, the first variable correspond to 2θ, and the third variable correspond to an intensity of the spectrum; and that the second variable correspond to an ordinal number indicating that the X-ray diffraction spectrum has been measured in an n-th measurement.

In the above-described structure, the first graph is preferably displayed in grayscale or color.

In the above-described structure, it is preferable that the measurement of the waveform such as the spectrum be X-ray diffraction spectrum measurement; that, in the first graph, a plurality of X-ray diffraction spectra with 2θ on an x-axis and a spectrum intensity on a y-axis be arranged in order of measurement with an offset provided in a direction of the y-axis; and that the x-axis and the y-axis be orthogonal to each other in the first graph.

In the above-described structure, it is preferable that the second graph be a graph with the voltage on the x-axis and elapsed time from a start of the measurement, capacity of the secondary battery, or capacity normalized with weight or volume of a positive electrode active material on the y-axis; that the x-axis and the y-axis be orthogonal to each other in the second graph; and that the first graph and the second graph be arranged side by side in a direction of the x-axis so that the direction of the y-axis of the first graph and the direction of the y-axis of the second graph are the same on the display portion.

Note that items indicated on the x- and y-axis are not limited to the above. For example, the items indicated on the x- and y-axis may be reversed.

In the above-described structure, it is preferable that the information processing device include an input device and that the input device be configured to receive either or both of charge conditions and discharge conditions of the secondary battery and to receive measurement conditions of the spectrum measurement.

In the above-described structure, it is preferable that the arithmetic portion be configured to generate a third graph using a set of data including the voltage and the time of measurement of the voltage; the display portion be configured to display the third graph; and that the third graph be a graph showing a relation between a value obtained by differentiating capacity of the secondary battery with respect to the voltage and the voltage of the secondary battery.

One embodiment of the present invention is a battery evaluation method including: a first step of outputting a first signal causing either or both of charge and discharge of a secondary battery from a signal input/output portion; a second step of outputting a second signal causing measurement of an X-ray diffraction spectrum repeatedly from the signal input/output portion in a first period in which either or both of the charge and the discharge of the secondary battery is performed; a third step of generating a second graph using a set of data including a voltage of the secondary battery and time of measurement of the voltage; a fourth step of generating a first graph using a plurality of X-ray diffraction spectra obtained by the repeated measurements; a fifth step of displaying the first graph and the second graph on a display portion; a sixth step of receiving a first area in one of the first graph and the second graph from an input device; a seventh step of displaying the received first area on the display portion so that the received first area is superimposed on the one of the first graph and the second graph; an eighth step of calculating, by an arithmetic portion, a second area corresponding to an area of time at which data of the first area has been measured, which is set in the other of the first graph and the second graph; and a ninth step of displaying the calculated second area on the display portion so that the calculated second area is superimposed on the other of the first graph and the second graph.

One embodiment of the present invention is a program for executing the above-described battery evaluation method on a computer.

One embodiment of the present invention is a non-transitory computer-readable recording medium storing a computer program which executes the above-described battery evaluation method on a computer.

In the above-described structure, it is preferable that the first signal be output from the signal input/output portion to a charge and discharge device and that the second signal be output from the signal input/output portion to an X-ray diffraction device.

In the above-described structure, it is preferable that the first graph be a graph in which the plurality of X-ray diffraction spectra are arranged in one direction in order of measurement; that the X-ray diffraction spectra each have a peak derived from a material included in the secondary battery; and that the second graph be a graph showing a relation between the voltage of the secondary battery and elapsed time of measurement or a relation between the voltage of the secondary battery and capacity of the secondary battery.

With one embodiment of the present invention, an excellent method for evaluating a secondary battery can be provided. With one embodiment of the present invention, an excellent system for evaluating a secondary battery can be provided. With one embodiment of the present invention, a method for easily linking a plurality of measurement methods relating to a secondary battery can be provided. With one embodiment of the present invention, a system that performs evaluation by easily linking a plurality of measurement methods relating to a secondary battery can be provided.

With one embodiment of the present invention, a method for dynamically linking a plurality of measurement methods relating to a secondary battery can be provided. With one embodiment of the present invention, a system that performs evaluation by dynamically linking a plurality of measurement methods relating to a secondary battery can be provided. With one embodiment of the present invention, a novel evaluation method can be provided. With one embodiment of the present invention, a novel evaluation system can be provided.

Note that the description of these effects does not preclude the existence of other effects. One embodiment of the present invention does not necessarily achieve all the effects. Other effects will be apparent from and can be derived from the description of the specification, the drawings, the claims, and the like.

### BRIEF DESCRIPTION OF THE DRAWINGS

In the accompanying drawings:

FIG. 1A is a block diagram illustrating a structure example of a battery evaluation system of one embodiment of the present invention, and FIGS. 1B and 1C are diagrams illustrating examples of a display portion;

FIGS. 2A to 2D illustrate examples of graphs;

FIGS. 3A and 3B illustrate examples of graphs;

FIG. 4 is a flow chart illustrating an operation example of a battery evaluation system of one embodiment of the present invention;

FIGS. 5A to 5C illustrate examples of graphs;

FIG. 6 is a flow chart illustrating an operation example of a battery evaluation system of one embodiment of the present invention;

FIGS. 7A and 7B are each an external view of a secondary battery;

FIGS. 8A and 8B each illustrate a cross section of a secondary battery;

FIG. 9 is a diagram illustrating a display portion of a battery evaluation system; and

FIG. 10 is a diagram illustrating a display portion of a battery evaluation system.

### DETAILED DESCRIPTION OF THE INVENTION

Embodiments will be described in detail with reference to the drawings. Note that the present invention is not limited to the following description, and it will be readily appreciated by those skilled in the art that modes and details can be modified in various ways without departing from the spirit and scope of the present invention. Therefore, the present invention should not be construed as being limited to the description in the following embodiments. Note that in the structures of the invention described below, the same portions or portions having similar functions are denoted by the same reference numerals in different drawings, and description of such portions is not repeated.

Ordinal numbers such as “first” and “second” in this specification and the like are used in order to avoid confusion among components and do not denote the priority or the order such as the order of steps or the stacking order. A term without an ordinal number in this specification and the like might be provided with an ordinal number in a claim in order to avoid confusion among components. A term with an ordinal number in this specification and the like might be provided with a different ordinal number in a claim. Moreover, a term with an ordinal number in this specification and the like might not be provided with any ordinal number in a claim and the like.

In this specification and the like, a space group is represented using the short symbol of the international notation (or the Hermann-Mauguin notation). In addition, the Miller index is used for the expression of crystal planes and crystal orientations. In the crystallography, a bar is placed over a number in the expression of space groups, crystal planes, and crystal orientations; in this specification and the like, because of format limitations, space groups, crystal planes, and crystal orientations are sometimes expressed by placing a minus sign (−) in front of a number instead of placing a bar over the number. Furthermore, an individual direction that shows an orientation in crystal is denoted by “[ ]”, a set direction that shows all of the equivalent orientations is denoted by “< >”, an individual plane that shows a crystal plane is denoted by “( )”, and a set plane having equivalent symmetry is denoted by “{ }”. A trigonal system represented by the space group R−3m is generally represented by a composite hexagonal lattice for easy understanding of the structure and is represented by a composite hexagonal lattice also in this specification and the like unless otherwise specified. In some cases, not only (hkl) but also (hkil) is used as the Miller index. Here, i is −(h+k). In this specification and the like, a crystal plane or the like in the space group R−3m is represented with use of a composite hexagonal lattice, unless otherwise specified.

### Embodiment 1

In this embodiment, a structure example of a battery evaluation system of one embodiment of the present invention and an operation example will be described.

With the battery evaluation system of one embodiment of the present invention, a material included in a secondary battery can be evaluated while the secondary battery is operated. The battery evaluation system of one embodiment of the present invention can evaluate a material included in a secondary battery by operando measurement (also referred to as in-situ measurement) while the secondary battery is operated. Here, as a method for operating the secondary battery, making a current flow through the secondary battery is preferable, for example. As examples of operation of the secondary battery, charge, discharge, constant voltage holding, and constant current holding can be given. In the case where an XRD method is used as a method for evaluating a material included in a secondary battery, the battery evaluation system of one embodiment of the present invention can be expressed as an evaluation system using operando XRD or in-situ XRD.

The battery evaluation system of one embodiment of the present invention includes an information processing device. Data on a voltage or the like in an operation of a secondary battery and evaluation data regarding a material included in the secondary battery are linked together by the information processing device. As the information processing device, a desktop personal computer, a portable personal computer, a smartphone, a tablet terminal, or the like can be used, for example.

The information processing device of one embodiment of the present invention preferably has a function of controlling operation conditions of a secondary battery. Specifically, the information processing device preferably has a function of controlling charge conditions, discharge conditions, or the like of a secondary battery, for example. The information processing device of one embodiment of the present invention preferably has a function of controlling evaluation conditions regarding a material included in a secondary battery.

The battery evaluation system of one embodiment of the present invention includes a charge and discharge device. When a secondary battery is electrically connected to the charge and discharge device, the secondary battery is preferably charged or discharged. For example, a secondary battery can be charged by a power supply included in the charge and discharge device. For example, a secondary battery can be discharged to a load included in the charge and discharge device.

The charge and discharge device preferably has a function of measuring data such as a voltage or a current of a secondary battery when the secondary battery is charged or discharged. The measured data is preferably stored in the information processing device in the state of being linked with the time of data measurement.

The battery evaluation system preferably has a function of controlling either or both of charge conditions and discharge conditions of a secondary battery. The information processing device can be equipped with the controlling function.

Alternatively, the charge and discharge device can be equipped with the controlling function. The information processing device may be equipped with part of the controlling function and the charge and discharge device may be equipped with the other of the controlling function.

The battery evaluation system of one embodiment of the present invention includes a measurement device regarding a secondary battery material. Data measured by the measurement device is preferably stored in the information processing device in the state of being linked with the time of data measurement.

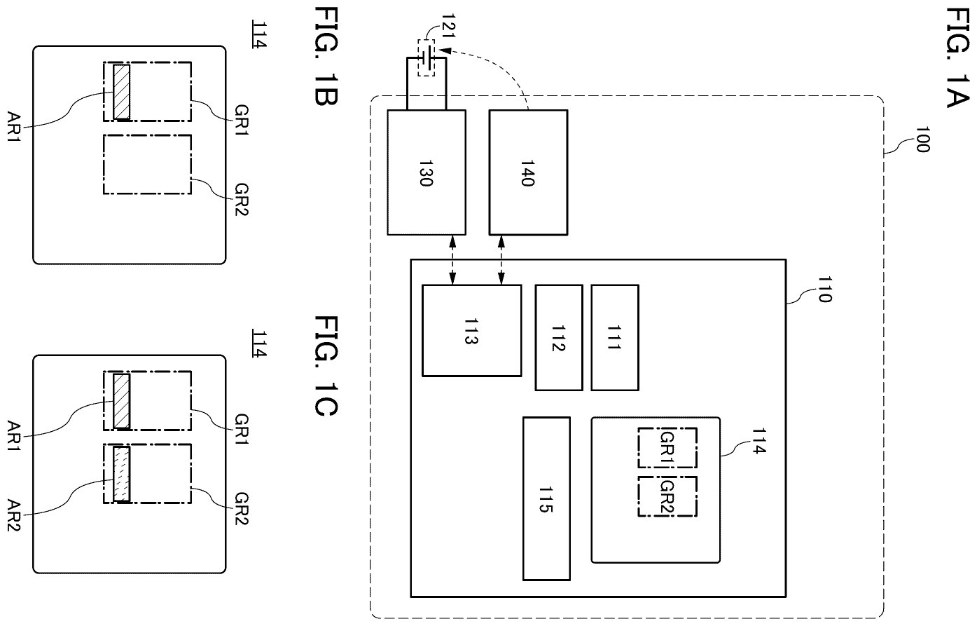

Here, the measurement device regarding a secondary battery material, for example, corresponds to a first measurement device 140 illustrated in FIG. 1A, which is described later.

The measurement device regarding a secondary battery material preferably performs measurement to grasp a change of properties of a battery material in a charge or discharge process. For example, by performing measurement every time the charge depth changes by a predetermined value, the measurement device can grasp a change of properties of a battery material caused by a change of a charge depth. With a higher measurement frequency, a change of properties can be grasped in more detail.

In the case where an X-ray diffraction device is used as the measurement device regarding a secondary battery material, an X-ray diffraction spectrum is repeatedly obtained with a frequency that is high enough to grasp a change of properties of a battery material in a charge or discharge process. For example, with the same 2θ measurement area, measurement of an X-ray diffraction spectrum is repeated. For example, in charge and discharge cycles, time required for one cycle of charge or discharge is divided into 10 or more periods, 20 or more periods, 50 or more periods, further preferably 200 or more periods, and one of the periods is set as a measurement cycle of the X-ray diffraction spectrum.

As a radiation source of the X-ray diffraction device, Cu, Mo, or the like can be used.

In the X-ray diffraction device, any of various detectors such as a zero-dimensional detector (referred to as a point detector or a scintillation detector in some cases), a one-dimensional detector, and a two-dimensional detector can be used. At the time of detection, a sweep of the X-ray emission angle is possible, for example. Alternatively, a sweep of the angle of the detector is possible. Furthermore, sweeps of both the X-ray emission angle and the angle of the detector are possible. With the use of a one-dimensional detector or a two-dimensional detector, measurement over a wide measurement area can be performed at once with the incident angle and the angle of the detector unchanged. Even in the case of using a one-dimensional detector or a two-dimensional detector, measurement is sometimes performed while the incident angle and the angle of the detector are changed.

It is preferable to use a one-dimensional detector or a two-dimensional detector because measurement time can be shortened and the measurement frequency can be increased with such a detector. The one-dimensional detector is, in general, a detector having a linear (one-dimensional) shape. The two-dimensional detector has a planar (two-dimensional) shape and thus can measure 2θ angle in a wide range at once. Note that as the one-dimensional measurement result, not only the result of measurement using the one-dimensional detector but also the result obtained by processing data measured using the two-dimensional detector to one-dimensional data may be used.

The information processing device preferably includes an arithmetic portion. The arithmetic portion can analyze data measured by the charge and discharge device and data measured by the measurement device regarding a secondary battery material and detect data measured at the same time or substantially the same time. In the case where measurement is repeatedly performed by the measurement device regarding a secondary battery material, the arithmetic portion can detect data measured by the charge and discharge device corresponding to data of measurement performed in a predetermined cycle.

Here, the time which the data measured by the charge and discharge device is linked with and the time which the data measured by the measurement device regarding a secondary battery material is linked with are preferably measured by the same clock built in the information processing device. When the data measured by the two devices are linked with the time measured by the same clock, the evaluation accuracy of the battery evaluation system can be increased. Linking data measured by two devices with the time measured by the same clock can also be expressed as synchronizing two devices with the clock built in the information processing device. Furthermore, the time linked with the measurement data may be the time relative to a certain time. The time relative to a certain time is referred to as elapsed time in some cases. Instead of the time of measurement, a cycle number of measurement, the measurement interval of the repeated measurements, or the like may be linked with the measurement data.

The information processing device preferably includes a display portion. The display portion can display, for example, a first graph generated using the data measured by the measurement device regarding a secondary battery material and a second graph generated using the data measured by the charge and discharge device. A programming language such as Python (registered trademark) or JavaScript (registered trademark) can be used in generating the graphs. For example, a graph generated using JavaScript can be dynamically operated using a Web browser. Generation of a graph can be rephrased as “visualization”.

The information processing device preferably includes an input device.

The input device has a function of receiving charge conditions of a secondary battery, discharge conditions of a secondary battery, measurement conditions regarding a secondary battery material, a measurement interval of the case where measurement is repeatedly performed, the number of measurements, or the like. A user of the battery evaluation system can input such conditions with the input device.

The information processing device has a function of supplying a signal based on the charge conditions and a signal based on the discharge conditions, which are input with the input device, to the charge and discharge device. The charge and discharge device performs charge and discharge of the secondary battery on the basis of the supplied signals.

Furthermore, the information processing device has a function of supplying a signal based on the input measurement conditions to the measurement device regarding a secondary battery material. The measurement device regarding a secondary battery material performs measurement regarding a secondary battery material on the basis of the supplied signals.

### <Structure Example of Battery Evaluation System>

FIG. 1A illustrates a structure example of the battery evaluation system.

A battery evaluation system 100 illustrated in FIG. 1A includes an information processing device 110, a charge and discharge device 130, and the first measurement device 140. The battery evaluation system 100 has a function of evaluating a secondary battery 121.

The charge and discharge device 130 is electrically connected to the secondary battery 121. The charge and discharge device 130 has a function of charging the secondary battery 121. In addition, the charge and discharge device 130 preferably has a function of discharging the secondary battery 121.

The charge and discharge device 130 may have a function of protecting the secondary battery. For example, the charge and discharge device 130 may include an overcharge detection circuit, an overdischarge detection circuit, an overcurrent detection circuit, a short-circuit detection circuit, or the like. With these detection circuits, the state of the secondary battery is monitored and the charge or discharge conditions are controlled in accordance with the state, whereby a higher safety of the secondary battery can be achieved.

In the case where the secondary battery 121 includes a plurality of battery cells, particularly, a plurality of serially connected battery cells, the charge and discharge device 130 may include a cell balancing circuit which controls charge and discharge of the plurality of battery cells.

The first measurement device 140 has a function of measuring a material included in the secondary battery 121 in a period when charge and discharge of the secondary battery 121 are performed.

The first measurement device 140 performs, as its measurement method, one selected from an X-ray diffraction method, Raman spectroscopy, infrared spectroscopy, an X-ray absorption fine structure (XAFS) method, a neutron diffraction method, X-ray photoelectron spectroscopy (XPS), observation with a laser microscope, observation with a scanning spread resistance microscope (SSRM), and the like, for example.

As the material that the first measurement device 140 can measure, one or more selected from a positive electrode material, a negative electrode material, an electrolyte material, a separator material, an exterior body material, and the like can be given.

The first measurement device 140 preferably has a function of measuring a waveform such as a spectrum, for example. As the measured waveform, one selected from a spectrum such as an X-ray diffraction spectrum, a Raman spectrum, an infrared spectrum, or a XANES spectrum obtained by XAFS, neutron diffraction data, an XPS spectrum, data containing positional information observed with a laser microscope, data containing positional information observed with an SSRM, and the like can be given. The waveform such as a spectrum obtained by the measurement with the first measurement device 140 preferably has a peak derived from the material included in the secondary battery.

Although the battery evaluation system 100 includes one first measurement device 140 in the example illustrated in FIG. TA, the battery evaluation system 100 may include a plurality of first measurement devices 140. In such a case, the first measurement devices 140 may perform different measurement methods from each other, for example.

The information processing device 110 illustrated in FIG. TA includes an arithmetic portion 111, a memory portion 112, a signal input/output portion 113, a display portion 114, and an input device 115.

The arithmetic portion 111 has a function of performing an arithmetic operation on the basis of a supplied signal. For example, the arithmetic portion 111 has a function of performing an arithmetic operation using data measured by external devices such as the charge and discharge device 130 and the first measurement device 140. Here, the external devices such as the charge and discharge device 130 and the first measurement device 140 are devices which exchange data with the internal components of the information processing device 110 via the signal input/output portion 113 of the information processing device 110.

The memory portion 112 has a function of storing data measured by an external device. Furthermore, the memory portion 112 has a function of storing data calculated by the arithmetic portion 111.

The arithmetic portion 111 has a function of executing a program stored in the memory portion 112.

Note that the program executed by the arithmetic portion 111 may be written in any of a variety of programming languages such as Python, Go, Perl, Ruby, Prolog, Visual Basic (registered trademark), C, C++, Swift, Java (registered trademark), and JavaScript, or a markup language such as Hypertext Markup Language (html) in combination with any of the programming languages. Alternatively, the program may be written in a style sheet language such as Cascading Style Sheets (CSS). Note that a programming language in this specification and the like also refers to a markup language and a style sheet language.

The program executed by the arithmetic portion 111 may include a plurality of programs written in the same programming language or a plurality of programs written in different programming languages.

For example, a plurality of programs, each for a different function, may be all written in the same programming language and used collectively as one program. For example, a plurality of programs may be all written in Python and used in combination as one program.

For example, part or all of a plurality of programs, each for a different function, may be written in different programming languages and used in combination as one program. For example, a program written in Python and a program written in JavaScript may be combined and used as one program. For example, a program written in JavaScript may be written in html. Html can be executed using any of a variety of Web browsers. Therefore, any of a variety of information processing devices can be used to form the battery evaluation system of one embodiment of the present invention.

The arithmetic portion 111 can execute a program, whereby various processings can be performed. For example, a signal generated by the arithmetic portion 111 can be supplied to a device included in the battery evaluation system 100, for example, the external device such as the first measurement device 140. Furthermore, for example, using data measured by a device included in the battery evaluation system 100, the arithmetic portion 111 can perform an arithmetic operation. Furthermore, for example, by supplying a signal from the arithmetic portion 111 to the display portion 114, desired information can be displayed on the display portion 114. Furthermore, for example, a result of the arithmetic operation by the arithmetic portion 111 can be stored in the memory portion 112. Furthermore, for example, using data stored in the memory portion 112, the arithmetic portion 111 can perform an arithmetic operation.

The signal input/output portion 113 has a function of supplying data measured by the external devices such as the charge and discharge device 130 and the first measurement device 140 to a circuit or the like included in the information processing device 110. The signal input/output portion 113 has a function of supplying a signal from the circuit or the like included in the information processing device 110 to the external devices.

The signal input/output portion 113 has a function of supplying data measured by the external devices to the arithmetic portion 111 and a function of supplying a signal generated by the arithmetic portion 111 to the external devices, for example.

Signal transfer between the components included in the information processing device 110 may be performed via the signal input/output portion 113. For example, information supplied to the input device 115 by the user may be supplied to the arithmetic portion 111 via the signal input/output portion 113. Moreover, a signal generated in the arithmetic portion 111 may be supplied to the display portion 114 via the signal input/output portion 113.

The display portion 114 has a function of displaying information such as a graph on the basis of the supplied signal.

The input device 115 has a function of receiving an input from the user of the battery evaluation system 100. Information input to the input device 115 is, for example, supplied to the arithmetic portion 111. Alternatively, information input to the input device 115 is, for example, supplied to the signal input/output portion 113.

The information input to the input device 115 is, after being processed by the arithmetic portion 111, the signal input/output portion 113, or the like, supplied to the charge and discharge device 130 or the first measurement device 140, in some cases.

As the input device 115, a touch sensor provided so as to overlap with the display portion 114 can be used, for example. Alternatively, for example, a pointing device that points at a desired region on the display portion 114 can be used. Alternatively, for example, a keyboard can be used.

The display portion 114 performs display of a graph using the data generated in the arithmetic portion 111, display of information input from the input device 115, and display of an arithmetic result based on the input information, for example. They can be displayed by executing the above-described program written in a programming language. The program may include a plurality of programs written in the same programming language or a plurality of programs written in different programming languages.

### <Function Example 1 of Battery Evaluation System>

An example of functions of the battery evaluation system 100 is described with reference to FIG. 1B and FIG. 1C.

The arithmetic portion 111 has a function of generating data of a graph GR1 on the basis of the data measured by the first measurement device 140. In addition, the arithmetic portion 111 has a function of generating data of a graph GR2 on the basis of the data measured by the charge and discharge device 130.

The display portion 114 has a function of displaying the graph GR1 and the graph GR2.

The user of the battery evaluation system 100 can select an area in the graph GR1 with the input device 115. FIG. 1B illustrates an example in which an area AR1 is selected.

A touch sensor or a pointing device can be used as the input device 115 to point at the area AR1 in the graph GR1 on the display portion 114. Alternatively, a keyboard can be used as the input device 115 to input numerical data corresponding to the information of the area AR1, for example. Alternatively, a slide bar set on the screen may be operated with a touch sensor or a pointing device and the area AR1 may be input in accordance with the state of the slide bar. Operation of the slide bar and the operation of inputting the area in accordance with the state of the slide bar can be performed by JavaScript, for example. Note that the slide bar is also referred to as a slider, a slider bar, or a range slider, in some cases.

The user of the battery evaluation system 100 can, for example, extract a characteristic part of the graph GR1 or the graph GR2 and select an area including the extracted area as the area AR1. The characteristic part means a part of a graph having an inflection point, a part where high spectrum intensity is detected, or a part where a change in the peak position of the spectrum has an inflection point, for example.

Since the graph GR1 and the graph GR2 are linked with the time of measurement, the arithmetic portion 111 can calculate an area AR2 in the graph GR2 as an area corresponding to the selected area AR1. The arithmetic portion 111 calculates an area in the graph GR2, which corresponds to the time when the data included in the area AR1 is obtained, as the area AR2.

The display portion 114 preferably has a function of displaying the calculated area AR2. For example, the area AR2 is preferably displayed so as to be superimposed on the graph GR2 on the display portion 114.

The area AR1 and the area AR2 can be expressed by a variety of methods. For example, two lines may be put on the graph and the region located between the two lines may be designated as the area. The lines may be any of a variety of lines such as solid lines, dotted lines, and chain lines and are preferably displayed in a color with high viewability. An arrow, a triangular marker, or the like may be used instead of the lines. In the case of using an arrow or a marker, an inward arrow or marker may be put on the left edge, the right edge, or both edges of a plot region of a graph without overlapping with the plot region, for example.

The user of the battery evaluation system 100 may select an area in the graph GR2. In that case, the arithmetic portion 111 calculates an area in the graph GR1, which corresponds to the selected area in the graph GR2, and the display portion 114 displays the area on the basis of the results calculated by the arithmetic portion 111.

### <Display Examples of Spectrum>

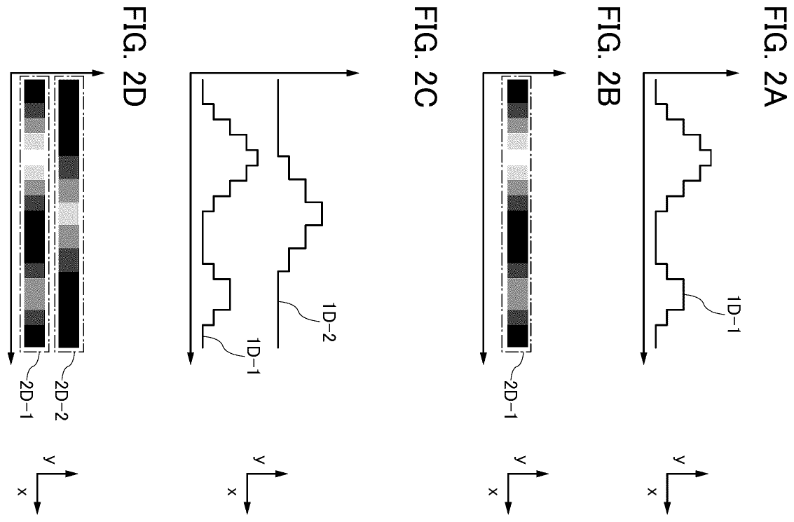

Examples of displaying one or more spectra in a graph are described with reference to FIG. 2A to FIG. 2D.

A spectrum 1D-1 illustrated in FIG. 2A is a spectrum with spectrum intensity on the y-axis. Note that the spectrum intensity may be a normalized value. For example, the x-axis represents an independent variable of the spectrum and, in the case of the X-ray diffraction spectrum, 2θ. FIG. 2B illustrates a spectrum showing the spectrum intensity of the spectrum 1D-1 by color gradation.

FIG. 2C illustrates the spectrum 1D-1 and a spectrum 1D-2 arranged in order in the y-axis direction. In FIG. 2C, the spectrum 1D-1 and the spectrum 1D-2 are each a spectrum with an independent variable of the spectrum, for example, on the x-axis and the spectrum intensity on the y-axis. In the spectrum 1D-2, an origin point of the graph is positively shifted in the y-axis direction.

FIG. 2D illustrates a spectrum 2D-1 and a spectrum 2D-2 arranged in order in the y-axis direction. The spectrum 2D-1 and the spectrum 2D-2 show the spectrum intensities of the spectrum 1D-1 and the spectrum 1D-2, respectively, by color gradation.

In this specification and the like, a spectrum or a plurality of spectra representing the spectrum intensity on the y-axis in the xy plane as in FIG. 2A and FIG. 2C is/are referred to as one-dimensionally displayed spectrum or spectra. Furthermore, in this specification and the like, a spectrum or a plurality of spectra showing the spectrum intensity by color gradation as in FIG. 2B and FIG. 2D is/are referred to as two-dimensionally displayed spectrum or spectra. Color gradation can be displayed by, for example, grayscale display, color display, or the like. In the color display, the spectrum intensity can be shown by brightness of color, a change of color, or the like.

Furthermore, the spectrum intensity can be shown by dot display, contour display, stereoscopic display, or the like.

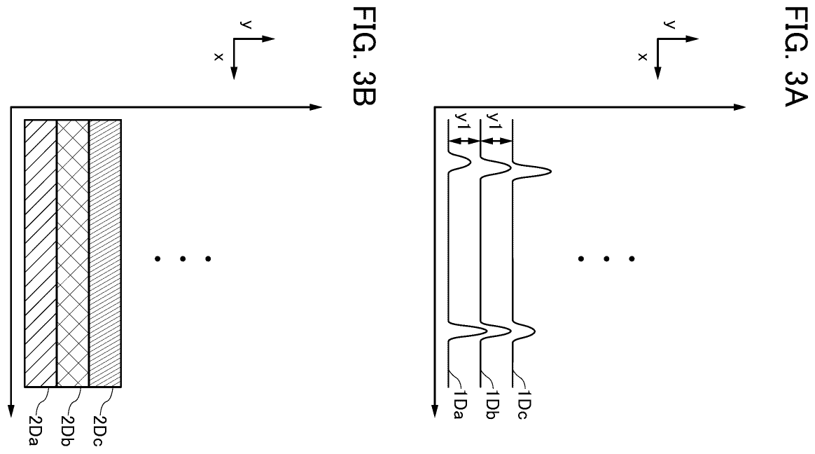

The spectrum repeatedly measured by the first measurement device 140 can be, for example, shown in the order of measurement along the y-axis direction as one-dimensionally displayed spectra as in FIG. 3A. As an example, FIG. 3A illustrates spectra 1Da, 1db, and 1Dc and does not illustrate spectra measured after the spectrum 1Dc.

Note that the one-dimensionally displayed spectra are arranged in order in the y-axis direction with an interval therebetween. For example, in the case where n spectra (n is an integer greater than or equal to 2) are arranged in order in the y-axis direction, the y coordinate value of the origin point of an m-th spectrum (m is an integer greater than or equal to 2 and less than or equal to n) is a value obtained by adding a graph interval y1 to the y coordinate value of the origin point of an (m−1)-th spectrum. The graph interval can also be referred to as an offset.

In the one-dimensionally displayed spectra, the m-th spectrum is a spectrum with an independent variable of the spectrum, for example, on the x-axis and the sum of the spectrum intensity and the y coordinate value of the origin point on the y-axis. In the above-described example, in the case where the y coordinate of the origin point of the first spectrum is 0, the y coordinate of the origin point of the m-th spectrum is m×y1. Note that it is possible that not all the spectra are displayed on the graph, and every other spectrum or every few spectra may be displayed.

FIG. 3B illustrates an example in which two-dimensionally displayed spectra are shown along the y-axis direction. As an example, FIG. 3B illustrates spectra 2Da, 2db, and 2Dc and does not illustrate spectra measured after the spectrum 2Dc. The spectra 2Da, 2db, and 2Dc show the spectrum intensities of the spectra 1Da, 1db, and 1Dc, respectively, by color gradation.

### <Operation Example 1 of Battery Evaluation System>

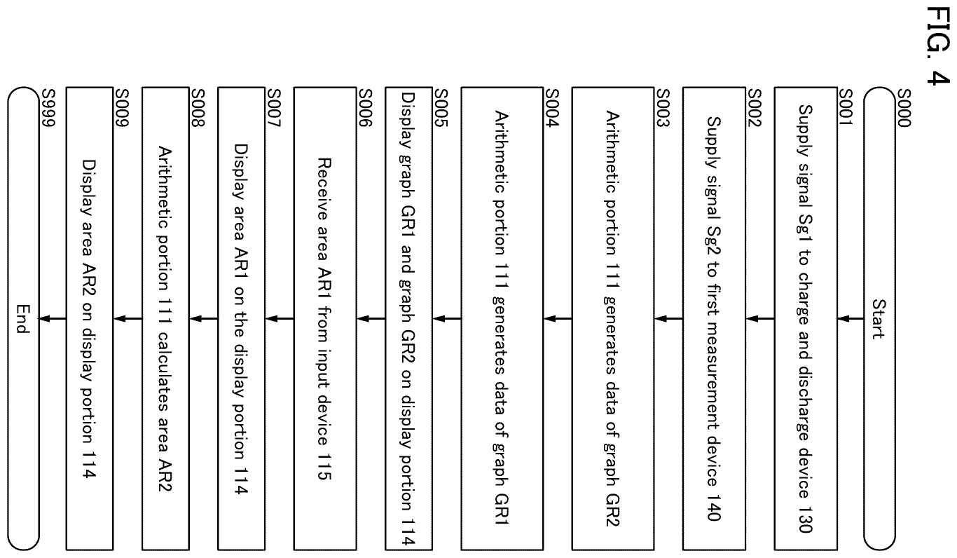

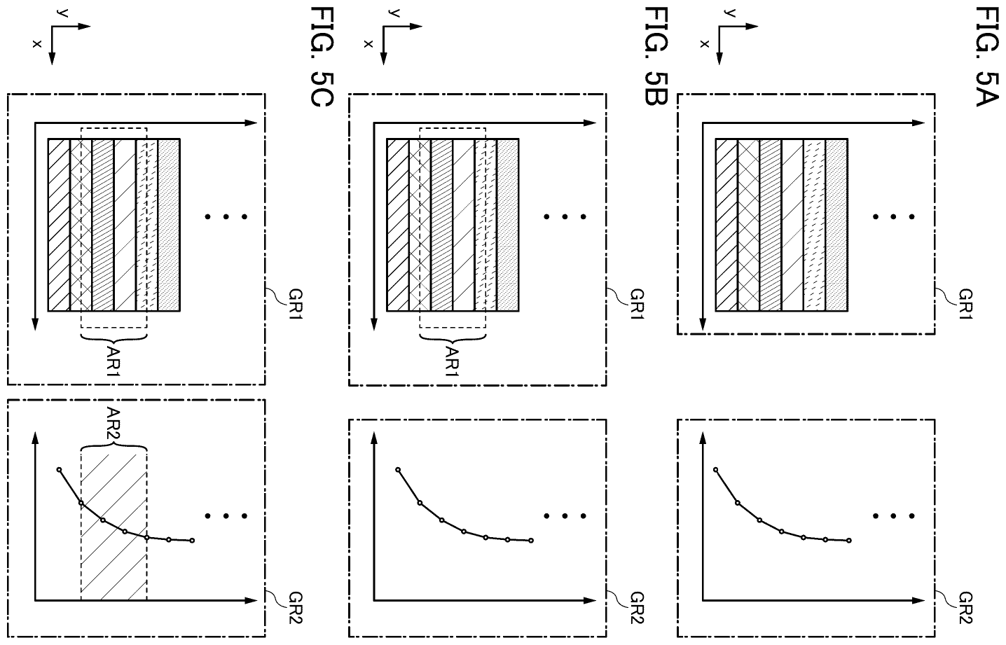

An operation example of the battery evaluation system 100 is described with reference to FIG. 4 and FIGS. 5A to 5C.

An operation example of the battery evaluation system 100 is described along a flow chart of FIG. 4. Each step in the flow chart of FIG. 4 are, for example, included in a program for operating the battery evaluation system 100.

First, processing in Step S000 starts. At the start of the processing, the arithmetic portion 111 reads a program stored in the memory portion 112 and starts executing the program, for example.

Next, in Step S001, a signal Sg1 is supplied to the charge and discharge device 130. The signal Sg1 is, for example, generated in the arithmetic portion 111 on the basis of information input from the input device 115 and is supplied from the arithmetic portion 111 via the signal input/output portion 113 to the charge and discharge device 130. The charge and discharge device 130 performs measurement of the secondary battery 121 on the basis of the supplied signal Sg1.

Next, in Step S002, a signal Sg2 is supplied to the first measurement device 140. The signal Sg2 is, for example, generated in the arithmetic portion 111 on the basis of information input from the input device 115 and is supplied from the arithmetic portion 111 via the signal input/output portion 113 to the first measurement device 140. The first measurement device 140 performs measurement of a material included in the secondary battery 121 on the basis of the supplied signal Sg2.

Step S001 and Step S002 are not necessarily performed in this order. For example, Step S002 may be performed prior to Step S001. Part or all of the processing in Step S001 and Step S002 may be performed at the same time. Step S001 and Step S002 may be repeated.

Next, in Step S003, the information processing device 110 obtains data measured by the charge and discharge device 130, and the arithmetic portion 111 generates data of the graph GR2. The arithmetic portion 111 generates the data of the graph GR2 using the data measured by the charge and discharge device 130 and the time linked with the measurement data.

In Step S004, the information processing device 110 obtains data measured by the first measurement device 140, and the arithmetic portion 111 generates data of the graph GR1. The arithmetic portion 111 generates the data of the graph GR1 using the data measured by the first measurement device 140 and the time linked with the measurement data.

The data measured by the charge and discharge device 130 and the first measurement device 140 is supplied via the signal input/output portion 113 to components of the information processing device 110 such as the arithmetic portion 111. At this time, the data measured by the charge and discharge device 130 and the first measurement device 140 is linked with the time of measurement using a clock included in the information processing device 110. A set of data including the measurement data and the time linked together is stored in the memory portion 112, for example.

Step S003 and Step S004 are not necessarily performed in this order. For example, Step S004 may be performed prior to Step S003. Part or all of the processing in Step S003 and Step S004 may be performed at the same time.

Next, in Step S005, the graph GR1 and the graph GR2 are displayed on the display portion 114.

FIG. 5A illustrates an example of the graph GR1 and the graph GR2 displayed on the display portion 114. As the graph GR1, a diagram of two-dimensionally displayed spectra arranged in the y-axis direction in order of measurement is illustrated. The x-axis of the graph GR1 can represent an independent variable of the spectrum (e.g., 2θ in the case of X-ray diffraction). The y-axis is described later.

As the graph GR2, a graph with measurement time on the y-axis and the voltage of the secondary battery on the x-axis is illustrated.

Note that the measurement time may be a relative value. Specifically, for example, a value relative to a certain time may be used.

In the case where the graph GR1 and the graph GR2 are arranged side by side in the horizontal direction (x-axis direction), it is preferable to match the y-axes of the graph GR1 and the graph GR2 with each other so that data measured at substantially the same time are displayed side by side at the same y coordinate.

The y-axis of the graph GR1 is described. In the graph GR1, the y-axis origin point of each of the spectra can be a value corresponding to the time of measurement of the spectrum.

In this case, the y-axis values of the graph GR1 and the graph GR2 each correspond to the time of measurement.

In the graph GR1, the time of measurement is not necessarily used in the y-axis, for example. In the graph GR1, the y-axis origin point of each of the spectra can be a measurement cycle number of X-ray diffraction, for example.

In this case, a value obtained by normalizing cumulative measurement time with the cycle period of the X-ray diffraction measurement (e.g., a value obtained by dividing cumulative measurement time by the cycle period of the X-ray diffraction measurement) is used as the y-axis of the graph GR2, so that the y-axes of the graph GR1 and the graph GR2 can match with each other.

The y-axis range of the graph GR1 is preferably substantially the same as that of the graph GR2. In the battery evaluation system of one embodiment of the present invention, when the arithmetic portion 111 generates data of the graph GR1 and data of the graph GR2, the data of the graphs are preferably generated so that the graphs can have substantially the same y-axis range. The arithmetic portion 111 preferably generates the data of the graphs such that, in the case where the y-axis range of one of the graphs is changed, the y-axis range of the other graph is also changed correspondingly.

Next, in Step S006 to Step S009, the area AR1 is received, and display of the area AR2 based on the area AR1 is performed. Step S006 to Step S009 can be performed repeatedly. Step S006 to Step S009 may be omitted.

First, in Step S006, the area AR1 in the graph GR1 is received from the input device 115. Next, in Step S007, the received area AR1 is displayed on the display portion 114.

As illustrated in FIG. 5B, the user of the battery evaluation system 100 can point at the area AR1 on the graph GR1 with the input device 115.

Next, in Step S008, the arithmetic portion 111 calculates the area AR2. The arithmetic portion 111 can calculate the area AR2 in the graph GR2 as an area corresponding to the selected area AR1. The arithmetic portion 111 calculates an area in the graph GR2, which corresponds to the time when the data included in the area AR1 is obtained, as the area AR2.

Next, in Step S009, the area AR2 is displayed on the display portion 114.

As illustrated in FIG. 5C, the calculated area AR2 can be displayed so as to be superimposed on the graph GR2.

Here, Step S007 to Step S009 are sequentially performed in response to the reception of the area AR1 from the input device 115 in Step S006.

Step S006 to Step S009 are performed repeatedly, for example. The starting point or endpoint of the area AR1 displayed in Step S006 is dragged with a mouse, so that the position of the starting point or endpoint is moved. In response to the position movement, Step S007 to Step S009 are sequentially performed, so that the position of the starting point or endpoint of the area AR2 is moved. That is, in response to a change of the area AR1, the area AR2 is changed correspondingly.

Next, in Step S999, the processing ends.

Note that different programs may be executed for Step S001, Step S002, and Step S003 to Step S009.

### <Operation Example 2 of Battery Evaluation System>

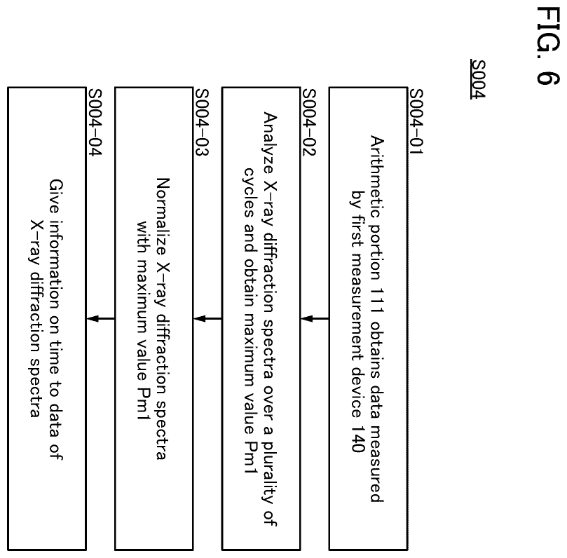

A specific example of the processing in Step S004 in FIG. 4 is described with reference to FIG. 6. In FIG. 6, Step S004 is further divided into four steps, Step S004-01 to Step S004-04.

In Step S004-01, the data measured by the first measurement device 140 is obtained by the arithmetic portion 111. The measurement data is supplied to the arithmetic portion 111 via the signal input/output portion 113, for example. The measurement data is stored in the memory portion 112 via the arithmetic portion 111, for example. Here, a case where an X-ray diffraction device is used as the first measurement device 140 and X-ray diffraction spectra are measured over a plurality of cycles is described as an example.

Next, in Step S004-02, the arithmetic portion 111 reads and analyzes the X-ray diffraction spectra over the plurality of cycles stored in the memory portion 112 and obtains a maximum value Pm1. Here, the maximum value Pm1 is the maximum peak intensity of the X-ray diffraction spectra over the plurality of cycles. The maximum value Pm1 may be obtained from the entire range of the spectra or may be calculated using the values in a predetermined 2θ range of the spectra. Instead of the maximum value over the plurality of cycles, the maximum value in each cycle may be used to perform normalization every cycle.

Next, in Step S004-03, the X-ray diffraction spectra is normalized with the maximum value Pm1. In the normalization, the spectrum intensity may be divided by the maximum value Pm1, or in the case where the spectrum intensity is low, the spectrum intensity may be divided by the maximum value Pm1 and then multiplied by a specific value.

In Step S004-03, the peak position may be determined for the X-ray diffraction spectrum of each cycle. The determination of the peak position may be performed by differentiation, for example. Alternatively, a value having a maximum value in the designated range may be the peak value. Data subjected to smoothing, background processing, or the like may be used as necessary. Note that Step S004-03 may be performed separately after visualization, as well as at the time of X-ray data reading operation.

Next, in Step S004-04, information on the time when the spectrum was measured is given to each of the X-ray diffraction spectra over the plurality of cycles. The given information on the time can be elapsed time from a certain reference time, for example.

Here, as a representative time value of one whole cycle of X-ray diffraction spectrum measurement, a certain point of time in the measurement period is used. For example, information on the time given to the one whole cycle of X-ray diffraction spectrum measurement may correspond to the measurement start time or the measurement end time of the X-ray diffraction spectrum, or a certain point of time between the measurement start time and the measurement end time.

In the case where the X-ray diffraction spectrum is measured repeatedly at intervals of certain measurement time, the time given to each spectrum can be expressed as the product of the measurement interval and the number of cycles of X-ray diffraction measurements, the sum of a constant and the product of the measurement interval and the number of cycles, or the like, for example.

### <Components of Battery Evaluation System>

Components included in the battery evaluation system 100 are described below.

### [Arithmetic Portion 111]

As the arithmetic portion 111, a central processing unit (CPU), a graphics processing unit (GPU), or the like can be used. Furthermore, the arithmetic portion 111 may be obtained with a programmable logic device (PLD) such as a field programmable gate array (FPGA) or a field programmable analog array (FPAA).

### [Memory Portion 112]

The memory portion 112 is preferably a memory which has a function of storing programs and parameters related to the operation of the battery evaluation system 100 and which is at least partly rewritable. The memory portion 112 can include a volatile memory, such as a random access memory (RAM), or a nonvolatile memory, such as a read only memory (ROM).

For example, a dynamic random access memory (DRAM) is used as a RAM provided in the memory portion 112. A memory space is assigned to part of the RAM as a workspace of the information processing device 110. The information processing device 110 may include an auxiliary memory device. An operating system, an application program, data, and the like that are stored in the auxiliary memory device are read into the RAM for execution.

As the ROM provided in the memory portion 112, a mask ROM, a one-time programmable read only memory (OTPROM), an erasable programmable read only memory (EPROM), or the like can be used. As an EPROM, an ultra-violet erasable programmable read only memory (UV-EPROM) which can erase stored data by irradiation with ultraviolet rays, an electrically erasable programmable read only memory (EEPROM), a flash memory, and the like can be given. The ROM can store a basic input/output system (BIOS), firmware, and the like for which rewriting is not needed.

The auxiliary memory device is a memory device that stores an operating system, an application program, data, and the like. In addition, a variety of parameters that are used in the arithmetic portion 111 are sometimes stored in the auxiliary memory device.

Examples of the auxiliary memory device are a memory device including a nonvolatile memory element, such as a flash memory, a magnetoresistive random access memory (MRAM), a phase change random access memory (PRAM), a resistive random access memory (ReRAM), or a ferroelectric random access memory (FeRAM); a memory device including a volatile memory element, such as a DRAM or a static random access memory (SRAM); and the like. Alternatively, a storage media drive such as a hard disk drive (HDD) or a solid state drive (SSD) may be used, for example.

Alternatively, a memory device that can be detached through the signal input/output portion 113, such as an HDD or an SSD, may be used as the auxiliary memory device, for example. In addition, a media drive for a computer-readable recording medium such as a flash memory, a Blu-ray (registered trademark) disc, a DVD, or a USB memory can be used as the auxiliary memory device.

### [Signal Input/Output Portion 113]

The signal input/output portion 113 has a function of controlling signal input/output between an external device and the information processing device 110. As an external port included in the signal input/output portion 113, an HDMI (registered trademark) terminal, a USB terminal, a terminal for LAN (Local Area Network) connection, or the like may be used. In addition, the signal input/output portion 113 may have a transmission and reception function for optical communication using infrared rays, visible light, ultraviolet rays, or the like. The signal input/output portion 113 also functions as an interface for an information input unit such as a mouse, a keyboard, a pen tablet, or a touch panel (touch sensor).

### [Display Portion 114]

As the display portion 114, any of a variety of display devices can be used. Examples of the display devices include a liquid crystal display device, a light-emitting display device including a light-emitting element such as an electroluminescent (EL) element in each pixel, an electrophoretic display device, a digital micromirror device (DMD), a plasma display panel (PDP), and a field emission display (FED).

### [Input Device 115]

As the input device 115, a touch sensor, a keyboard, a pointing device, or the like can be used. The touch sensor can be provided so as to overlap with the display screen of the display portion 114. A mouse, a touch pad, a stylus, or the like can be used as the pointing device. Note that a touch sensor and a keyboard are sometimes included in the pointing device.

### [Charge and Discharge Device 130]

The charge and discharge device 130 has a function of charging a secondary battery. The charge and discharge device 130 can perform charge such as constant current charge or constant voltage charge on the basis of charge conditions supplied from the information processing device 110. The charge and discharge device 130 can control an upper-limit charge voltage or the like of a secondary battery.

The charge and discharge device 130 has a function of discharging a secondary battery. The charge and discharge device 130 can perform discharge such as constant current discharge on the basis of discharge conditions supplied from the information processing device 110. The charge and discharge device 130 can control a lower-limit charge voltage or the like of a secondary battery.

### [First Measurement Device 140]

As a measurement method that the first measurement device 140 employs, an X-ray diffraction method, Raman spectroscopy, infrared spectroscopy, an XAFS method, a neutron diffraction method, XPS, observation with a laser microscope, observation with an SSRM, or the like can be used. An exterior body of a secondary battery preferably includes metal foil because an X-ray or a neutron beam easily passes through the exterior body including metal foil of the secondary battery and thus measurement using an X-ray or a neutron beam is possible without disassembly of the secondary battery.

Furthermore, a window that is formed of a material through which light such as visible light, infrared light, or ultraviolet light easily passes, such as quartz or fluoride glass, is preferably provided for an exterior body of a secondary battery, in which case measurement using such light can be performed without disassembly of the secondary battery.

The measurement by the first measurement device 140 enables identification of a compound or evaluation of the crystal structure, bonding state, valence of metal, crystal defects, degree of orientation, surface roughness, information on material's expansion and contraction, material's electric resistance, or the like regarding components of a secondary battery such as a positive electrode (e.g., a positive electrode active material, a conductive material, and a binder), a negative electrode (e.g., a negative electrode active material, a conductive material, and a binder), an electrolyte, a separator, and an exterior body in a charge process or a discharge process of the secondary battery.

### <X-Ray Diffraction Device>

As the first measurement device 140, an X-ray diffraction device is preferably used. As an X-ray source of the X-ray diffraction device, a radiation source with a Mo tube is preferably used, in which case an X-ray can easily pass through components, such as an exterior body, a positive electrode, and a negative electrode, of a secondary battery. The tube that can be used is not limited to the Mo tube. Any of a variety of X-ray sources with Cu, Co, Cr, or Ag tubes can be used in accordance with the measurement purpose or the like.

From the information on the peak position or the like of the X-ray diffraction spectra obtained by an X-ray diffraction method, the crystal structure can be identified, or the lattice constant can be determined, for example. Furthermore, from the information on the peak width or the like of the X-ray diffraction spectra, the crystallite size can be determined.

By an X-ray diffraction method, a positive electrode active material included in a positive electrode or a negative electrode active material included in a negative electrode can be analyzed, for example.

The display portion 114 can display a graph of the lattice constant or the peak position linked with measurement time, in addition to the X-ray diffraction spectra. The peak position can be obtained, for example, in Step S004-03. Also in the graph of the lattice constant, the area that changes in response to a change in the area selected in the other graph can be displayed.

### <Material Database>

The battery evaluation system 100 may include a material database. The material database is a database of the properties of existing materials. The material's properties may be obtained using Crystallographic Information File (CIF) publicly opened at ICSD or the like. Alternatively, a database provided by International Centre for Diffraction Data (ICDD), National Institute of Standards and Technology (NIST), Cambridge Structural Database (CSD), or Pauling File may be used. Material's properties can also be obtained from a variety of databases other than the above. As the material's properties, not only data obtained from the databases but also simulated data may be used. Furthermore, material's properties may be data obtained through an experiment or the like by the user. The material's properties are referred to as literature values, in some cases.

Examples of items registered in the material database include material name, space group number, plane indices, interplanar spacing, peak position, and relative peak intensity. The peak position and the relative peak intensity are prepared in accordance with the X-ray source to be used. The items registered in the database are not limited to these and may be other various items. The registered items can be used for searching.

The material database can be stored in the auxiliary memory device included in the information processing device 110, for example. Alternatively, the material database may be stored in a server, a cloud system, or the like connected via wired or wireless communication through the signal input/output portion 113 or a communication device. The material database may be written in a program executed by the arithmetic portion 111. Specifically, for example, a JavaScript array embedded in html and converted by Python is searched using JavaScript, and a graph or a table is drawn using JavaScript.

A material database which collects data of particularly frequently used materials in accordance with the material structure of a secondary battery evaluated by the battery evaluation system 100 may be written in a program executed by the arithmetic portion 111. The user can search the particularly frequently used materials, whereby search time can be shortened. Furthermore, the user can add material data to this material database at any time.

As the program that writes the material database, any of a variety of languages can be used. As a specific example here, Python is used.

Any of a variety of languages can be used also for a program for displaying the material database written with a program on the display portion 114. Specifically, for example, an input portion which selects the material database can be provided for a page displayed in html with a program written in JavaScript. Alternatively, with a program written in JavaScript, the material database can be selected or searched. For example, the input portion may be written in html and decorated by CSS.

Any of a variety of languages such as JavaScript can also be used for a program for adding new data to the material database.

The information processing device 110 has a function of displaying information on the peak position or the like of a found material on the display portion 114 on the basis of information in the material database. The user of the information processing device 110 can select, with the input device 115, a material whose information is to be displayed on the display portion 114. A graph showing the peak position of X-ray diffraction for a selected material is displayed on the display portion 114, for example. Here, the peak position of X-ray diffraction may be displayed so as to be superimposed on the graph GR1, for example. Alternatively, a graph showing the peak position of X-ray diffraction and the graph GR1 may be displayed next to each other vertically or horizontally.

The information processing device 110 may have a function of comparing the peak position of an X-ray diffraction spectrum measured by the first measurement device 140 with information on the peak positions registered in the material database and searching for a material corresponding to the peak of the measured X-ray diffraction spectrum.

The information processing device 110 can search the material database with the peak position and intensity of the measured X-ray diffraction spectrum as clues.

The information processing device 110 may designate the area of the peak position when searching the material database. The area of the peak position can be set freely by the user. For example, the area may include the peak position and its neighborhood of the measured X-ray diffraction spectrum. A plurality of areas of peak positions may be used for searching; data satisfying any of the plurality of areas (data having a peak in any of the plurality of areas), data satisfying all of the plurality of areas (data having a peak in each of the plurality of areas), or the like can be searched for as appropriate.

As an example, here, an area of greater than or equal to 100 and less than or equal to 150 and an area of greater than or equal to 20° and less than or equal to 250 are given as a first area and a second area, respectively. The information processing device 110 may have a function of searching data satisfying the first area (data having a peak at greater than or equal to 10° and less than or equal to 15°), data satisfying the first area and the second area (data having a peak at greater than or equal to 10° and less than or equal to 150 and a peak at greater than or equal to 200 and less than or equal to 25°), or data satisfying the first area or the second area (data having a peak at greater than or equal to 100 and less than or equal to 150 or at greater than or equal to 200 and less than or equal to 25°). The conditions described above as an example can be set freely.

In the case where a plurality of possible matched materials are presented, only peaks having peak intensities higher than a certain value in X-ray diffraction spectra are searched for among the peaks used for matching of the peak position, whereby the search accuracy can be increased. As the peak intensity, a relative peak intensity normalized with the maximum value is preferably used.

The parameters used for searching are not limited to the peak position and the peak intensity. For example, a parameter such as the material name, space group number, plane indices, interplanar spacing, or lattice constant can be used to search for a material corresponding to the measured X-ray diffraction spectrum. These may be used in combination for searching.

### <Charge and Discharge Curve>

The display portion 114 can display a charge and discharge curve with cumulative capacity on the horizontal axis and voltage on the vertical axis, in addition to the graph GR1 and the graph GR2. The charge and discharge curve includes a curve corresponding to charge and a curve corresponding to discharge. Either a charge curve or a discharge curve may be shown in the charge and discharge curve. An area corresponding to the area AR1 may be shown in the charge and discharge curve.

A graph with the charge depth or discharge depth of a secondary battery, instead of the cumulative capacity, on the horizontal axis may be displayed.

<dQ/DV Measurement>

The display portion 114 can display dQ/dV-V curve linked with measurement time, in addition to the graph GR1 and the graph GR2. dQ/dV means the quantity of electricity Q differentiated with respect to voltage V; the quantity of electricity Q is capacity of a secondary battery here.

In the dQ/dV-V curve, an extremum corresponding to a change in the crystal structure in a positive electrode active material, a negative electrode active material, or the like of a secondary battery may be observed. Displaying a dQ/dV-V curve in addition to the graph GR1 and the graph GR2 facilitates evaluation of a secondary battery, in some cases. An area corresponding to the area AR1 may be shown in the dQ/dV-V curve.

Instead of the dQ/dV-V curve, a dV/dQ-V curve, a dV/dQ-Q curve, or the like may be displayed.

This embodiment can be implemented in appropriate combination with any of the other embodiments.

### Embodiment 2

In this embodiment, a structure example of a secondary battery will be described.

### <Structure Example of Secondary Battery>

As a secondary battery of one embodiment of the present invention, a secondary battery with any of a variety of shapes such as a rectangular shape, a cylindrical shape, a coin-type shape, and a flexible laminated shape can be used. A structure example of a laminated secondary battery is described below.

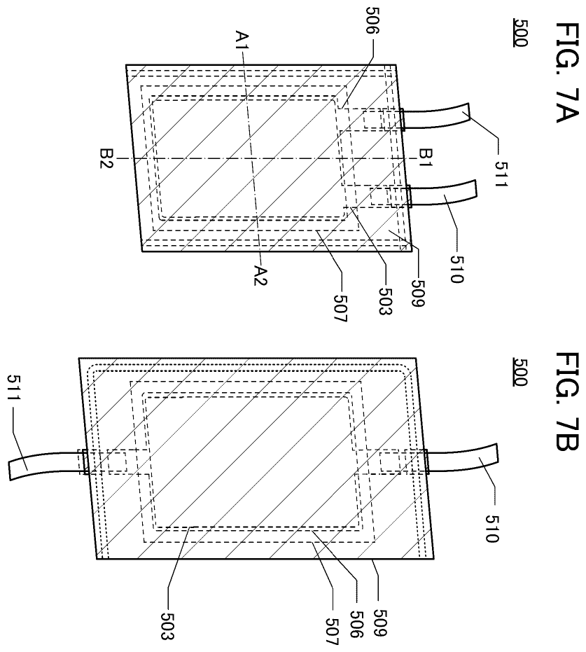

A secondary battery 500 illustrated in FIG. 7A and FIG. 7B includes a positive electrode 503, a negative electrode 506, a separator 507, an exterior body 509, a positive electrode lead electrode 510, and a negative electrode lead electrode 511.

The secondary battery 500 illustrated in FIG. 7A and FIG. 7B is sealed on three sides.

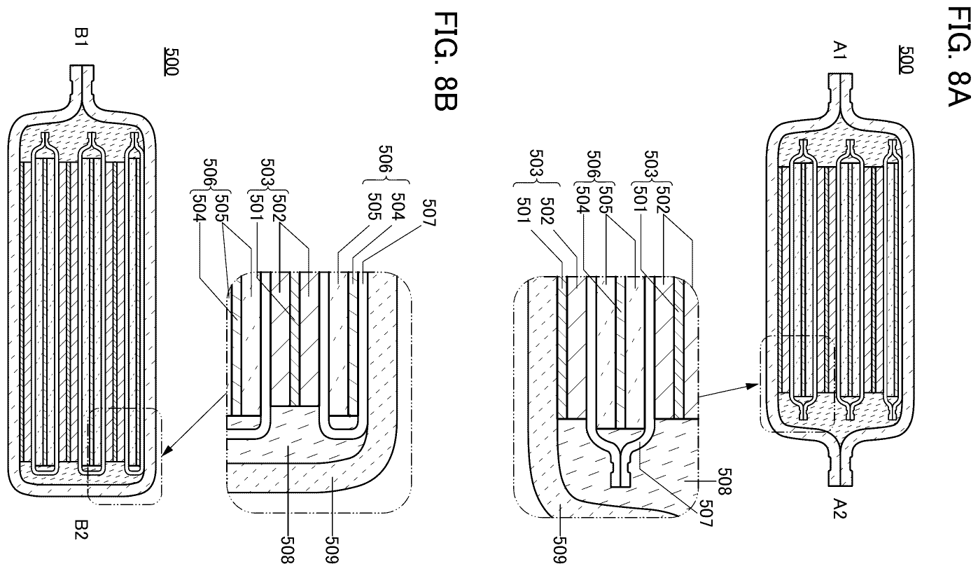

FIG. 8A illustrates an example of a cross-sectional view along dashed-dotted line A1-A2 in FIG. 7A, and FIG. 8B illustrates an example of a cross-sectional view along dashed-dotted line B1-B2 in FIG. 7A.

For the exterior body 509, one or more selected from metal materials such as aluminum and resin materials can be used, for example. A film-like exterior body can also be used. As the film, for example, it is possible to use a film having a three-layer structure in which a highly flexible metal thin film of aluminum, stainless steel, copper, nickel, or the like is provided over a film formed of a resin material such as polyethylene, polypropylene, polycarbonate, ionomer, polyamide, or polyimide, and an insulating synthetic resin film of a polyamide-based resin, a polyester-based resin, or the like is provided over the metal thin film as the outer surface of the exterior body.

A structure where part of the exterior body 509 does not include a metal may be used. For example, the exterior body 509 may be provided with a window region that does not include a metal thin film. A material that easily transmits X-rays is preferably used for the window region. For example, the window region may be formed of a resin material.

Alternatively, the window region may have a structure including beryllium that easily transmits X-rays.

In the positive electrode 503, for example, a layer containing a positive electrode active material (hereinafter, referred to as a positive electrode active material layer 502) is formed on both surfaces or one surface of a positive electrode current collector 501. In the negative electrode 506, for example, a layer containing a negative electrode active material (hereinafter, referred to as a negative electrode active material layer 505) is formed on both surfaces or one surface of a negative electrode current collector 504. The secondary battery 500 includes an electrolyte solution 508 in the exterior body 509.

The positive electrode 503 and the negative electrode 506 are stacked with the separator 507 therebetween. A stacked body formed of the positive electrode 503, the negative electrode 506, and the separator 507 is placed inside the exterior body 509.

The positive electrode active material layer 502 and the negative electrode active material layer 505 face each other with the separator 507 therebetween. The structure illustrated in FIGS. 8A and 8B includes five pairs, each pair including the positive electrode active material layer and the negative electrode active material layer facing each other with the separator therebetween.

The positive electrode current collector 501 includes a region bonded to the positive electrode lead electrode 510. For example, in the region, a structure where the positive electrode active material layer 502 is not provided over the positive electrode current collector 501 is used.

The negative electrode current collector 504 includes a region bonded to the negative electrode lead electrode 511. For example, in the region, a structure where the negative electrode active material layer 505 is not provided over the negative electrode current collector 504 is used.

The positive electrode lead electrode 510 and the negative electrode lead electrode 511 each include a region that is led to the outside of the exterior body 509. The region led to the outside of the exterior body 509 in each of the positive electrode lead electrode 510 and the negative electrode lead electrode 511 functions as a positive electrode terminal or a negative electrode terminal of the secondary battery 500.

Since an X-ray is absorbed by the current collectors, the active materials, and the like as well as the exterior body 509, stacking more pairs of positive and negative electrode active material layers makes X-ray transmission difficult. Therefore, in the case of performing evaluation with the battery evaluation system of one embodiment of the present invention, the number of pairs of positive and negative electrode active material layers is, for example, greater than or equal to one and less than or equal to ten, greater than or equal to one and less than or equal to five, or greater than or equal to one and less than or equal to three.

The active material layer preferably includes a conductor in addition to the active material. As the conductor, a sheet-like compound, a fibrous compound, or the like may be used. The sheet-like compound and the fibrous compound can form a three-dimensional conduction path, for example. When the sheet-like compound is placed to be in contact with a plurality of active materials, conductivity can be imparted to the plurality of active materials. Moreover, when the sheet-like compound is placed to wrap the surfaces of the active materials, the compound can make surface contact with the active materials, whereby the conductivity of the active material layer can be increased. A plurality of fibrous compounds can be in contact with each other in the thickness direction of the active material layer, for example, whereby a conduction path can be formed. Thus, the conductivity of the active material layer can be increased. As the sheet-like conductor, graphene can be used, for example. The graphene may be rounded like a carbon nanofiber. The conductors may form an aggregation. Formation of the aggregation by the conductors may increase the conductivity of the active material layer.

When a sheet-like carbon-containing compound or a fibrous carbon-containing compound is used as the conductor, the conductivity of the active material layer can be increased, so that a secondary battery suitable for rapid charge, rapid discharge, and the like can be provided.

The active material layer may include a binder in addition to the active material.

Alternatively, as the binder, a material such as polystyrene, poly(methyl acrylate), poly(methyl methacrylate) (PMMA), sodium polyacrylate, polyvinyl alcohol (PVA), polyethylene oxide (PEO), polypropylene oxide, polyimide, polyvinyl chloride, polytetrafluoroethylene, polyethylene, polypropylene, polyisobutylene, polyethylene terephthalate, nylon, poly(vinylidene fluoride) (PVDF), polyacrylonitrile (PAN), ethylene-propylene-diene polymer, polyvinyl acetate, or nitrocellulose is preferably used.

As the binder, a rubber material such as styrene-butadiene rubber (SBR), styrene-isoprene-styrene rubber, acrylonitrile-butadiene rubber, butadiene rubber, or ethylene-propylene-diene copolymer is preferably used, for example. Alternatively, fluororubber can be used as the binder.

As the binder, water-soluble polymer can be used. The water-soluble polymer is preferably added to the above-described rubber material, for example. As the water-soluble polymer, a polysaccharide can be used, for example. As the polysaccharide, one or more selected from starch, a cellulose derivative such as carboxymethyl cellulose (CMC), methyl cellulose, ethyl cellulose, hydroxypropyl cellulose, diacetyl cellulose, or regenerated cellulose, and the like can be used. It is further preferable that such a water-soluble polymer be used in combination with the above-described rubber material.

At least two of the above materials may be used in combination as the binder.

The positive electrode active material layer and the negative electrode active material layer can each be formed in the following manner, for example: a positive or negative electrode active material, a conductor, a binder, and a solvent are mixed to form slurry, the slurry is applied onto a current collector, and the solvent is volatilized. The solvent used for formation of the slurry is preferably a polar solvent. Examples of the material of the polar solvent include water, methanol, ethanol, acetone, tetrahydrofuran (THF), dimethylformamide (DMF), N-methylpyrrolidone (NMP), dimethyl sulfoxide (DMSO), and a mixed solution of any two or more of the above.

The positive electrode current collector and the negative electrode current collector can be formed using a highly-conductive material which is not alloyed with a carrier ion of lithium or the like, such as a metal typified by stainless steel, gold, platinum, zinc, iron, copper, aluminum, or titanium, or an alloy thereof. It is also possible to use an aluminum alloy to which an element that improves heat resistance, such as silicon, titanium, neodymium, scandium, or molybdenum, is added. A metal element that forms silicide by reacting with silicon may be used. Examples of the metal element that forms silicide by reacting with silicon include zirconium, titanium, hafnium, vanadium, niobium, tantalum, chromium, molybdenum, tungsten, cobalt, and nickel. The current collector can have a sheet-like shape, a net-like shape, a punching-metal shape, an expanded-metal shape, or the like as appropriate. The current collectors each preferably have a thickness greater than or equal to 10 m and less than or equal to 30 m.

Note that a material that is not alloyed with carrier ions of lithium or the like is preferably used as the negative electrode current collector.

The separator 507 can be formed using paper, nonwoven fabric, glass fiber, ceramics, or the like, for example. Alternatively, the separator 507 can be formed using nylon (polyamide), vinylon (polyvinyl alcohol-based fiber), polyester, acrylic, polyolefin, polyurethane, polypropylene, polyethylene, or the like. The separator is preferably formed to have an envelope-like shape to wrap one of the positive electrode and the negative electrode.

As the separator 507, for example, a polymer film including polypropylene, polyethylene, polyimide, or the like can be used. Owing to its high wettability with respect to an ionic liquid, polyimide may be further preferable as a material of the separator 507.

The separator may have a multilayer structure. For example, a structure in which two kinds of polymer materials are stacked may be employed.

Examples of the secondary battery include a secondary battery that utilizes an electrochemical reaction, such as a lithium ion battery, an electrochemical capacitor such as an electric double-layer capacitor or a redox capacitor, an air battery, and a fuel battery.

As a positive electrode material of the secondary battery, for example, a material including an element A, an element X, and oxygen can be used. The element A is preferably one or more elements selected from elements belonging to Groups 1 and 2. Examples of the elements belonging to Group 1 include alkali metals such as lithium, sodium, and potassium. Examples of the elements belonging to Group 2 include calcium, beryllium, and magnesium. Examples of the element X include one or more elements selected from metal elements, silicon, and phosphorus. The element X is preferably one or more elements selected from cobalt, nickel, manganese, iron, and vanadium.

Examples of a positive electrode active material include a lithium-containing composite oxide with an olivine crystal structure, a lithium-containing composite oxide with a layered rock-salt crystal structure, and a lithium-containing composite oxide with a spinel crystal structure.

As the lithium-containing composite oxide with an olivine crystal structure, a composite oxide represented by a general formula LiMPO₄ (M is one or more of Fe(II), Mn(II), Co(II), and Ni(II)) can be given, for example. Typical examples of the general formula LiMPO₄ include LiFePO₄, LiNiPO₄, LiCoPO₄, LiMnPO₄, LiFeₐNi_{b}PO₄, LiFeₐCo_{b}PO₄, LiFeₐMn_{b}PO₄, LiNiₐCo_{b}PO₄, LiNiₐMn_{b}PO₄ (a+b≤1, 0<a<1, and 0<b<1), LiFe_{c}Ni_{d}CoₑPO₄, LiFe_{c}Ni_{d}MnₑPO₄, LiNi_{c}Co_{d}MnₑPO₄ (c+d+e≤1, 0<c<1, 0<d<1, and 0<e<1), and LiFe_{f}Ni_{g}CoₕMnPO₄ (f+g+h+i≤1, 0<f<1, 0<g<1, 0<h<1, and 0<i<1).

As the lithium-containing composite oxide with a layered rock-salt crystal structure, a positive electrode active material represented by LiₓMO₂ (M is a metal) can be used, for example. As the positive electrode active material represented by LiₓMO₂, lithium cobalt oxide, lithium cobalt-nickel oxide, lithium nickel-cobalt-manganese oxide, lithium nickel-cobalt-aluminum oxide, lithium nickel-manganese-aluminum oxide, and the like can be given, for example. Examples of the lithium-containing composite oxide with a layered rock-salt crystal structure include LiCoO₂; LiNiO₂; LiMnO₂; Li₂MnO₃; an NiCo-based lithium-containing material (a general formula thereof is LiNiₓCo₁₋ₓO₂ (0<x<1)) such as LiNi_{0.8}Co_{0.2}O₂; an NiMn-based lithium-containing material (a general formula thereof is LiNiₓMn₁₋ₓO₂ (0<x<1)) such as LiNi_{0.5}Mn_{0.5}O₂; and an NiMnCo-based lithium-containing material (also referred to as NMC, and a general formula thereof is LiNiₓMn_{y}Co_{1-x-y}O₂ (x>0, y>0, x+y<1)) such as LiNi_{1/3}Mn_{1/3}Co_{1/3}O₂. Moreover, Li(Ni_{0.8}Co_{0.15}Al_{0.05})O₂, Li₂MnO₃-LiMO₂ (M=Co, Ni, or Mn), and the like can be given as the examples.

Examples of the lithium-containing composite oxide with a spinel crystal structure include LiMn₂O₄, Li₁₊ₓMn₂₋ₓO₄, LiMn₂₋ₓAlₓO₄, LiMn_{1.5}Ni_{0.5}O₄, and the like.

The electrolyte solution contains a solvent and an electrolyte. As the solvent of the electrolyte solution, an aprotic organic solvent is preferably used. For example, one of ethylene carbonate (EC), propylene carbonate (PC), butylene carbonate, chloroethylene carbonate, vinylene carbonate, γ-butyrolactone, γ-valerolactone, dimethyl carbonate (DMC), diethyl carbonate (DEC), ethyl methyl carbonate (EMC), methyl formate, methyl acetate, ethyl acetate, methyl propionate, ethyl propionate, propyl propionate, methyl butyrate, 1,3-dioxane, 1,4-dioxane, dimethoxyethane (DME), dimethyl sulfoxide, diethyl ether, methyl diglyme, acetonitrile, benzonitrile, tetrahydrofuran, sulfolane, and sultone can be used, or two or more of these solvents can be used in an appropriate combination at an appropriate ratio.

Alternatively, the use of one or more ionic liquids (room temperature molten salts) that are unlikely to burn and volatize as the solvent of the electrolyte solution can prevent a secondary battery from exploding and/or catching fire even when the secondary battery internally shorts out or the internal temperature increases owing to overcharge or the like. An ionic liquid contains a cation and an anion, specifically, an organic cation and an anion. Examples of the organic cation used for the electrolyte solution include aliphatic onium cations such as a quaternary ammonium cation, a tertiary sulfonium cation, and a quaternary phosphonium cation, and aromatic cations such as an imidazolium cation and a pyridinium cation. Examples of the anion used for the electrolyte solution include a monovalent amide-based anion, a monovalent methide-based anion, a fluorosulfonate anion, a perfluoroalkylsulfonate anion, a tetrafluoroborate anion, a perfluoroalkylborate anion, a hexafluorophosphate anion, and a perfluoroalkylphosphate anion.

As an electrolyte dissolved in the above-described solvent, a salt containing the element A can be used, for example.

Alternatively, a polymer gel electrolyte obtained in such a manner that a polymer is swelled with an electrolyte solution may be used. When a polymer gel electrolyte is used, safety against liquid leakage and the like is improved. Moreover, a secondary battery can be thinner and more lightweight.

Instead of the electrolyte solution, a solid electrolyte including an inorganic material such as a sulfide-based or oxide-based inorganic material, or a solid electrolyte including a polymer material such as a polyethylene oxide (PEO)-based polymer material may alternatively be used. When the solid electrolyte is used, a separator and/or a spacer is/are not necessary. Furthermore, the battery can be entirely solidified; therefore, there is no possibility of liquid leakage and thus the safety of the battery is dramatically improved.

Examples of the sulfide-based solid electrolyte include a thio-LISICON-based material (e.g., Li₁₀GeP₂Si₂ and Li_{3.25}Ge_{0.25}P_{0.75}S₄), sulfide glass (e.g., 70Li₂S·30P₂S₅, 30Li₂S·26B₂S₃·44LiI, 63Li₂S·36SiS₂·1Li₃PO₄, 57Li₂S·38SiS₂·5Li₄SiO₄, and 50Li₂S·50GeS₂), and sulfide-based crystallized glass (e.g., Li₇P₃S₁₁ and Li_{3.25}P_{0.95}S₄). Examples of the oxide-based solid electrolyte include a material having a perovskite crystal structure (e.g., La_{2/3-x}Li₃ₓTiO₃), a material having a NASICON crystal structure (e.g., Li₁₊ₓAlₓTi₂₋ₓ(PO₄)₃), a material having a garnet crystal structure (e.g., Li₇La₃Zr₂O₁₂), a material having a LISICON crystal structure (e.g., Li₁₄ZnGe₄O₁₆), LLZO (Li₇La₃Zr₂O₁₂), oxide glass (e.g., Li₃PO₄—Li₄SiO₄ and 50Li₄SiO₄·50Li₃BO₃), and oxide-based crystallized glass (e.g., Li_{1.07}Al_{0.69}Ti_{1.46}(PO₄)₃ and Li_{1.5}Al_{0.5}Ge_{1.5}(PO₄)₃). Examples of the halide-based solid electrolyte include LiAlCl₄, Li₃InBr₆, LiF, LiCl, LiBr, and LiI. Li₁₊ₓAlₓTi₂₋ₓ(PO₄)₃(0<x<1) having a NASICON crystal structure (hereinafter, LATP) is preferable because LATP contains aluminum and titanium, each of which is the element the positive electrode active material used in the secondary battery of one embodiment of the present invention is allowed to contain, and thus a synergistic effect of improving the cycle performance is expected. Moreover, higher productivity due to the reduction in the number of steps is expected. Note that in this specification and the like, a material having a NASICON crystal structure refers to a compound that is represented by M₂(XO₄)₃(M: transition metal; X: S, P, As, Mo, W, or the like) and has a structure in which MO₆ octahedra and XO₄ tetrahedra that share common corners are arranged three-dimensionally.

The secondary battery preferably includes a separator. The separator can be formed using, for example, paper, nonwoven fabric, glass fiber, ceramics, or synthetic fiber containing nylon (polyamide), vinylon (polyvinyl alcohol-based fiber), polyester, acrylic, polyolefin, or polyurethane.

In the case where a material containing the element A, the element X, and oxygen is used as a positive electrode active material, a material that enables charge and discharge reactions by insertion and extraction of ions of the element A, a material that enables charge and discharge reactions by alloying and dealloying reactions with the element A, or the like can be used as a negative electrode active material of the secondary battery.

Examples of the carbon-based material as the negative electrode active substance include graphite, graphitizing carbon (soft carbon), non-graphitizing carbon (hard carbon), a carbon nanotube, graphene, and carbon black.

Examples of the negative electrode active material include a material containing at least one of Al, Si, Ge, Sn, Pb, Sb, Bi, Ag, Zn, Cd, In, Ga, and the like. Such elements have higher capacity than carbon. In particular, silicon has a significantly high theoretical capacity of 4200 mAh/g. For this reason, silicon is preferably used as the negative electrode active material. Examples of the alloy-based material containing such elements include Mg₂Si, Mg₂Ge, Mg₂Sn, SnS₂, V₂Sn₃, FeSn₂, CoSn₂, Ni₃Sn₂, Cu₆Sns, Ag₃Sn, Ag₃Sb, Ni₂MnSb, CeSb₃, LaSn₃, La₃Co₂Sn₇, CoSb₃, InSb, and SbSn.

This embodiment can be implemented in appropriate combination with any of the other embodiments.

### Example

### <Fabrication of Secondary Battery>

First, a positive electrode active material was formed. As the positive electrode active material, lithium nickel-cobalt-manganese oxide was used.

As source materials, NiSO₄, CoSO₄, and MnSO₄ were used, and a coprecipitation reaction was performed using sodium hydroxide; thus, a precursor was formed. Then, the precursor and lithium hydroxide were mixed and baked at 700° C., whereby lithium nickel-cobalt-manganese oxide was obtained as the positive electrode active material.

Next, a positive electrode was formed.

First, the obtained positive electrode active material was mixed with acetylene black, PVDF, and NMP, whereby slurry to be a positive electrode active material layer was formed. The positive electrode active material, acetylene black, and PVDF were weighed at the weight ratio of 95:3:2.

The formed slurry was applied to one surface of an aluminum current collector. Then, a solvent was volatilized; thus, the positive electrode active material layer was formed over the current collector and the positive electrode was obtained. The loading amount of the positive electrode active material layer was 9.8 mg/cm². The area of the positive electrode active material layer in the positive electrode was approximately 20.5 cm². The thickness of the positive electrode active material layer was 32 m, and the density thereof was 3.2 g/cc.

Next, a negative electrode was formed. A negative electrode active material layer was formed over a copper current collector using graphite as a negative electrode active material, whereby the negative electrode was obtained. The loading amount of the negative electrode active material layer was 6.7 mg/cm². The thickness of the negative electrode active material layer was 57 m, and the density thereof was 1.2 g/cc.

Next, a secondary battery was fabricated using the obtained positive and negative electrodes.

As a solvent of an electrolyte solution, a solvent obtained by mixing EC, EMC, and DMC at EC:EMC:DMC=3:3.5:3.5 in volume was used. As a lithium salt of the electrolyte solution, LiPF₆ was used, and the concentration of the lithium salt with respect to the electrolyte solution was adjusted at 1 mol/L.

As a separator, polypropylene was used.

As a film to be an exterior body, a film in which a polypropylene layer, an acid modified polypropylene layer, an aluminum layer, and a nylon layer are stacked in this order was used. The thickness of the film was approximately 110 μm. The film to be the exterior body was bent so that the nylon layer was placed as the surface of the exterior body placed on the outer side and the polypropylene layer was placed as the surface of the exterior body placed on the inner side. The thickness of the aluminum layer was approximately 40 μm, the thickness of the nylon layer was approximately 25 μm, and the total thickness of the polypropylene layer and the acid modified polypropylene layer was approximately 45 μm.

A sheet of the negative electrode on one side of which the negative electrode active material layer was formed and a sheet of the positive electrode on one side of which the positive electrode active material layer was formed were made to overlap each other so that the active material layers face each other with the separator therebetween. The stacked positive electrode, negative electrode, and separator were placed inside the exterior body. Furthermore, the exterior body was sealed so that a lead electrode extends from each of the positive electrode and the negative electrode to the outside of the exterior body.

Then, aging was performed. At the aging, a current was made to flow through the secondary battery for a certain period of time. Then, one side of the exterior body was cut and opened, degasification was performed, and then sealing was performed again.

### <Evaluation of Secondary Battery>

The fabricated secondary battery was placed in a position where the secondary battery could be irradiated with an X-ray from an X-ray diffraction device. The positive electrode and the negative electrode of the secondary battery were electrically connected to a charge and discharge device. The secondary battery was placed in a position for transmission X-ray diffraction measurement. The secondary battery was fixed in position with a jig.

The secondary battery was placed between an X-ray emission unit and a detector such that a line connecting the X-ray emission unit and the detector passes through a top surface of the secondary battery.

The jig can be used to fix the secondary battery in position. As the jig, two plates for holding the secondary battery therebetween can be used. The jig preferably has a structure that easily transmits an X-ray. For example, the two plates may be provided with an opening in a region which an X-ray passes through. Alternatively, a structure which fixes only part of a peripheral region of the secondary battery may be used. As a material of the plates, a resin, a thin metal, or the like can be used. With the jig, not only is the secondary battery fixed in position, but also expansion of the exterior body of the secondary battery due to, for example, gas generation in charge and discharge operation can be suppressed. Note that a thermocouple may be provided for the jig to measure the temperature.

Next, processing was implemented in accordance with the flow chart illustrated in FIG. 4. The environmental temperature during the measurement was set at room temperature.

First, in Step S001, a signal for measurement was supplied to the charge and discharge device 130. This caused charge and discharge of the secondary battery by the charge and discharge device.

The charge conditions were as follows: an upper limit voltage of 4.4 V and a charge current of 8 μmA. The discharge conditions were as follows: a lower limit voltage of 3.0 V and a discharge current of 8 μmA. The rated capacity of the secondary battery was set at 40 μmAh. The charge rate and the discharge rate calculated on the basis of the rated capacity were each 0.2 C. The charge was performed by CCCV with a 0.02 C cut. A 1-hour down time was provided between charge and discharge operations.

In Step S002, a signal for measurement was supplied to the first measurement device 140, causing measurement by the X-ray diffraction device. A radiation source with a Mo tube was used as an X-ray source. Among X-rays generated from the X-ray source, a Mo Kα1 characteristic X-ray was used for the analysis. Note that the X-ray diffraction device used for the measurement has a one-dimensional detector. As a measurement area of the detector, a 2θ range was set to greater than or equal to 7° and less than or equal to 25°. The X-ray incident angle was set to 0° with respect to a stage of the X-ray diffraction device. The secondary battery was set so that the top surface of the secondary battery faces a substantially perpendicular direction with respect to the stage.

The time required for one cycle of X-ray diffraction measurement was approximately 60 seconds. The measurement was repeatedly performed 178 times with a measurement interval of 300 seconds to obtain X-ray diffraction spectra.

Here, in Step S001 and Step S002, the start time of the charge and discharge by the charge and discharge device and the start time of the spectrum obtainment by the X-ray diffraction device were set substantially the same. In the case where the start times for the measurements are different, either of the start time is regarded as a reference time.

Next, in Step S003, the information processing device obtained a voltage V of the secondary battery measured by the charge and discharge device and a time Tv when the voltage V was measured. The arithmetic portion generated, as data of the graph GR2, a set of data including the obtained voltage V and time Tv. The arithmetic portion further generated, as data of a charge and discharge curve, a set of data including the voltage V and a capacity Q which was calculated using the time Tv. Moreover, the arithmetic portion generated, as data of a dV/dQ-Q curve, a set of data including the capacity Q and [dV/dQ] which was calculated using the voltage V and the capacity Q. Note that the capacity Q refers to charge capacity or discharge capacity.

Furthermore, in Step S004, Step S004-01 to Step S004-04 illustrated in FIG. 6 were performed.

First, in Step S004-01, the information processing device obtained the plurality of X-ray diffraction spectra measured by the X-ray diffraction device.

Next, in Step S004-02, the arithmetic portion performed an arithmetic operation and detected the maximum value Pm1 in the X-ray diffraction spectra. Specifically, a maximum spectrum intensity value in a 2θ range from 7° to 10° in the plurality of X-ray diffraction spectra was extracted as the maximum value Pm1. As the peak in a 2θ range from 7° to 10° in the case of using a Mo Kα1 characteristic X-ray, a peak corresponding to (003) plane of LiNi_{0.8}Co_{0.1}Mn_{0.1}O₂ can be obtained.

Next, in Step S004-03, the arithmetic portion performed an arithmetic operation and normalized each of the obtained X-ray diffraction spectra using the maximum value Pm1.

Next, in Step S004-04, information on the measurement cycle of the X-ray diffraction spectra was given to each of the normalized X-ray diffraction spectra, whereby data of the graph GR1 was generated.

Although the measurement cycle was used here as the given information, a time Tx corresponding to the time of measurement can also be calculated using the product of a measurement interval of 300 seconds and the number of cycles.

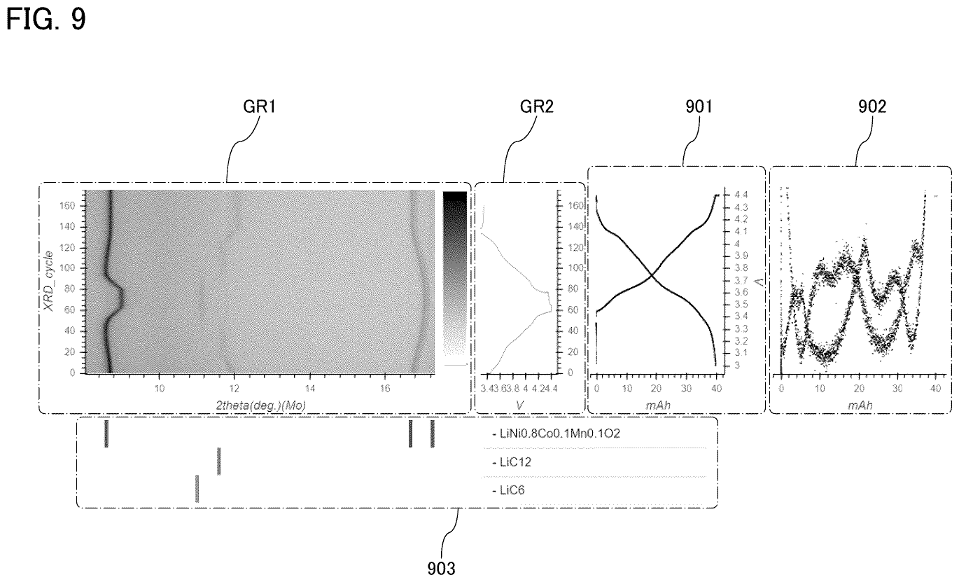

Next, in Step S005, the information processing device made each of the graph GR1, the graph GR2, a graph 901, a graph 902, and a graph 903 be displayed on the display portion as illustrated in FIG. 9 with the use of the data generated by the arithmetic portion.

The graph GR1 is a graph with 2theta (2θ) on the horizontal axis, XRD_cycle (the number of cycles of X-ray diffraction measurements) on the vertical axis, and spectrum intensity shown by color gradation in grayscale. Here, the number of cycles of X-ray diffraction measurements refers to the number of measurements in the case of repeating measurement.

The user can select which to display, the one-dimensionally displayed spectra or the two-dimensionally displayed spectra, in the graph GR1. The two-dimensionally displayed spectra are shown in FIG. 9.

The graph GR2 is a graph with voltage on the horizontal axis and values obtained by normalizing cumulative charge and discharge time with the cycle period of the X-ray diffraction measurement on the vertical axis. Here, the values on the vertical axis of the graph GR2 match the parameter on the vertical axis of the graph GR1, that is, XRD_cycle.

Although the time Tx can also be used on the vertical axis of the graph GR2, the values obtained by normalizing the time Tx with the cycle period of the spectrum measurement by the X-ray diffraction device (measurement interval) were used here to match with the vertical axis of the graph GR1.

As described above, XRD_cycle was used as the y-axis parameters displayed in both the graph GR1 and the graph GR2. In addition, the y-axis displayed range was also made the same in the graph GR1 and the graph GR2. By using the same y-axis parameter and the same y-axis range in the graph GR1 and the graph GR2, the X-ray diffraction spectrum and the measurement point of the charge and discharge data which are measured at the same time can be displayed at substantially the same y coordinate.

The graph 901 shows the charge and discharge curve. The graph 901 shows a charge curve with charge capacity on the horizontal axis and charge voltage on the vertical axis and a discharge curve with discharge capacity on the horizontal axis and discharge voltage on the vertical axis.

The graph 902 shows the dV/dQ-Q curve.

The graph 903 is a graph showing X-ray diffraction peak positions of LiNi_{0.8}Co_{0.1}Mn_{0.1}O₂, LiC₁₂, and LiC₆ using information contained in a material database.

Next, in Step S006, the area AR1 of the vertical axis in the graph GR1 was received. In Step S007, the area AR1 was displayed on the display portion. A bar indicating the starting point of the area AR1 and a bar indicating the endpoint of the area AR1 were dragged with a mouse as an input device to designate the position of the area AR1.

Next, in Step S008, the arithmetic portion calculated the area AR2 using the input data on the area AR1. In Step S009, the area AR2 was displayed on the display portion so as to be superimposed on the graph GR2.

Note that Step S006 to Step S009 are performed every time the position designation by a drag of the mouse is performed in an input of the area AR1 in Step S006. In other words, Step S006 to Step S009 are repeated until the area AR1 is determined.

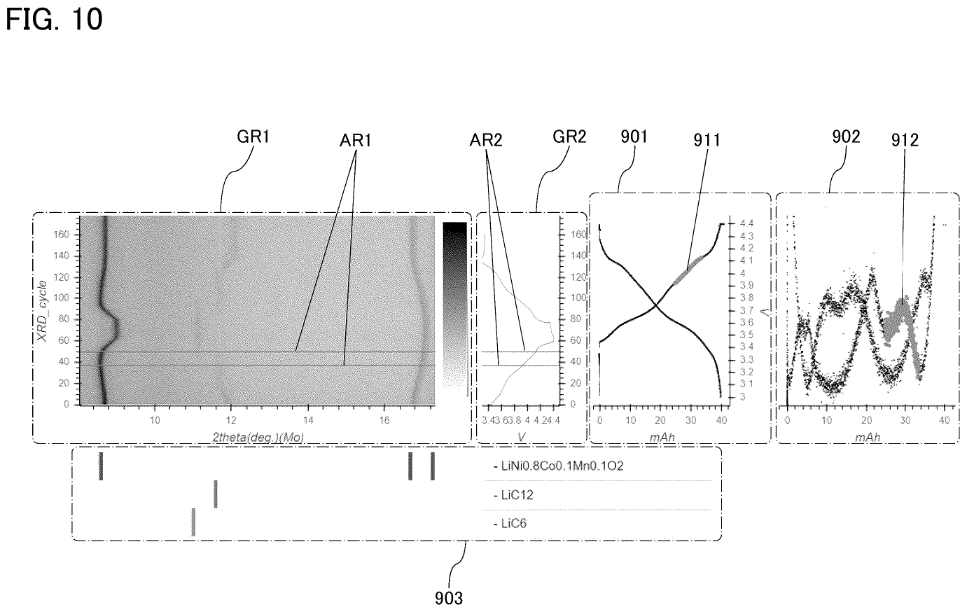

FIG. 10 illustrates the area AR1 and the area AR2 displayed on the display portion. In FIG. 10, an area 911 and an area 912 which correspond to the input area AR1 are shown with bold lines in the graph 901 and the graph 902, respectively,

Last, the processing ended in Step S999.

By the above-described processing in accordance with the flow chart in FIG. 4, measurement results and analysis results obtained with the battery evaluation system were displayed on the display portion of the information processing device.

This application is based on Japanese Patent Application Serial No. 2022-121332 filed with Japan Patent Office on Jul. 29, 2022, the entire contents of which are hereby incorporated by reference.

What is claimed is:

1. A battery evaluation system comprising:
a charge and discharge device;
a first measurement device; and
an information processing device,
wherein the information processing device comprises an arithmetic portion, a signal input/output portion, and a display portion,
wherein the signal input/output portion is configured to supply a signal to each of the charge and discharge device and the first measurement device,
wherein the charge and discharge device is configured to perform, in a first period, either or both of charge of a secondary battery and discharge of the secondary battery on the basis of the signal supplied from the signal input/output portion,
wherein the charge and discharge device is configured to measure a voltage of the secondary battery,
wherein the first measurement device is configured to perform, in the first period, measurement of a waveform such as a spectrum a plurality of times on the basis of the signal supplied from the signal input/output portion,
wherein the waveform such as the spectrum obtained by the measurement comprises information derived from a material included in the secondary battery,
wherein the arithmetic portion is configured to generate a first graph using the plurality of measured waveforms such as the spectra,
wherein the arithmetic portion is configured to generate data of a second graph using a set of data comprising the voltage and time at which the voltage has been measured,
wherein the display portion is configured to display the first graph and the second graph at the same time, and
wherein the battery evaluation system is configured to set a first area in one of the first graph and the second graph and to display a second area corresponding to the first area in the other of the first graph and the second graph.

2. The battery evaluation system according to claim 1,
wherein the waveform such as the spectrum is one selected from an X-ray diffraction spectrum, a Raman spectrum, an infrared spectrum, a XANES spectrum, an XPS spectrum, neutron diffraction data, data containing positional information observed with a laser microscope, and data containing positional information observed with an SSRM, and
wherein the spectrum obtained by the spectrum measurement has a peak derived from the material included in the secondary battery.

3. The battery evaluation system according to claim 1,
wherein the time at which the voltage has been measured and time at which the plurality of waveforms such as the spectra has been measured are synchronized by a clock built in the information processing device.

4. The battery evaluation system according to claim 1, further comprising an input device,
wherein the first area is set by data received from the input device.

5. The battery evaluation system according to claim 1,
wherein the second area corresponds to an area of time at which measurement of the first area has been conducted.

6. The battery evaluation system according to claim 1,
wherein the measurement of the waveform such as the spectrum is X-ray diffraction spectrum measurement,
wherein the first graph is a graph with a first variable on an x-axis, a second variable on a y-axis, and a third variable shown by color gradation of points on an xy plane,
wherein the x-axis and the y-axis are orthogonal to each other in the first graph,
wherein in the first graph, an X-ray diffraction spectrum is shown using a relation between the first variable and the third variable, the first variable corresponds to 2θ, and the third variable corresponds to an intensity of the spectrum, and
wherein the second variable corresponds to an ordinal number indicating how many times the X-ray diffraction spectrum has been measured.

7. The battery evaluation system according to claim 6,
wherein the first graph is displayed in grayscale or color.

8. The battery evaluation system according to claim 1,
wherein the measurement of the waveform such as the spectrum is X-ray diffraction spectrum measurement,
wherein in the first graph, a plurality of X-ray diffraction spectra with 2θ on an x-axis and a spectrum intensity on a y-axis are arranged in order of measurement with an offset provided in a direction of the y-axis, and
wherein the x-axis and the y-axis are orthogonal to each other in the first graph.

9. The battery evaluation system according to claim 6,
wherein the second graph is a graph with the voltage on the x-axis and elapsed time from a start of the measurement, capacity of the secondary battery, or capacity normalized with weight or volume of a positive electrode active material on the y-axis,
wherein the x-axis and the y-axis are orthogonal to each other in the second graph, and
wherein the first graph and the second graph are arranged side by side in a direction of the x-axis so that the direction of the y-axis of the first graph and a direction of the y-axis of the second graph are the same on the display portion.

10. The battery evaluation system according to claim 1,
wherein the information processing device comprises an input device, and
wherein the input device is configured to receive either or both of charge conditions and discharge conditions of the secondary battery and to receive measurement conditions of the spectrum measurement.

11. The battery evaluation system according to claim 1,
wherein the arithmetic portion is configured to generate a third graph using a set of data comprising the voltage and the time at which the voltage has been measured,
wherein the display portion is configured to display the third graph, and
wherein the third graph is a graph showing a relation between a value obtained by differentiating capacity of the secondary battery with respect to the voltage and the voltage of the secondary battery.

12. A battery evaluation method comprising:
a first step of outputting a first signal from a signal input/output portion, the first signal causing either or both of charge and discharge of a secondary battery;
a second step of outputting a second signal from the signal input/output portion in a first period in which either or both of the charge and the discharge of the secondary battery is performed, the second signal causing measurement of an X-ray diffraction spectrum repeatedly;
a third step of generating a second graph using a set of data comprising a voltage of the secondary battery and time at which the voltage has been measured;
a fourth step of generating a first graph using a plurality of X-ray diffraction spectra obtained by the repeated measurements;
a fifth step of displaying the first graph and the second graph on a display portion;
a sixth step of receiving a first area in one of the first graph and the second graph from an input device;
a seventh step of displaying the received first area on the display portion so that the received first area is superimposed on the one of the first graph and the second graph;
an eighth step of calculating, by an arithmetic portion, a second area corresponding to an area of time at which data of the first area has been measured, which is set in the other of the first graph and the second graph; and
a ninth step of displaying the calculated second area on the display portion so that the calculated second area is superimposed on the other of the first graph and the second graph.

13. A non-transitory computer-readable recording medium storing a computer program, the computer program executing the battery evaluation method according to claim 12 on a computer.

14. The battery evaluation method according to claim 12,
wherein the first signal is output from the signal input/output portion to a charge and discharge device, and
wherein the second signal is output from the signal input/output portion to an X-ray diffraction device.

15. The battery evaluation method according to claim 12,
wherein the first graph is a graph in which the plurality of X-ray diffraction spectra are arranged in one direction in order of measurement,
wherein the X-ray diffraction spectra each have a peak derived from a material included in the secondary battery, and
wherein the second graph is a graph showing a relation between the voltage of the secondary battery and elapsed time of measurement or a relation between the voltage of the secondary battery and capacity of the secondary battery.

16. A battery evaluation system comprising:
a charge and discharge device;
a first measurement device; and
an information processing device,
wherein the information processing device comprises an arithmetic portion and a signal input/output portion,
wherein the signal input/output portion is configured to supply a signal to each of the charge and discharge device and the first measurement device,
wherein the charge and discharge device is configured to perform, in a first period, either or both of charge of a secondary battery and discharge of the secondary battery on the basis of the signal supplied from the signal input/output portion,
wherein the charge and discharge device is configured to measure a voltage of the secondary battery,
wherein the first measurement device is configured to perform, in the first period, measurement of a waveform such as a spectrum a plurality of times on the basis of the signal supplied from the signal input/output portion,
wherein the waveform such as the spectrum obtained by the measurement comprises information derived from a material included in the secondary battery,
wherein the arithmetic portion is configured to generate a first graph using the plurality of measured waveforms such as the spectra,
wherein the arithmetic portion is configured to generate data of a second graph using a set of data comprising the voltage and time at which the voltage has been measured, and
wherein the battery evaluation system is configured to set a first area in one of the first graph and the second graph and to set a second area corresponding to the first area in the other of the first graph and the second graph.

17. The battery evaluation system according to claim 16,
wherein the waveform such as the spectrum is one selected from an X-ray diffraction spectrum, a Raman spectrum, an infrared spectrum, a XANES spectrum, an XPS spectrum, neutron diffraction data, data containing positional information observed with a laser microscope, and data containing positional information observed with an SSRM, and
wherein the spectrum obtained by the spectrum measurement has a peak derived from the material included in the secondary battery.

18. The battery evaluation system according to claim 16,
wherein the measurement of the waveform such as the spectrum is X-ray diffraction spectrum measurement,
wherein the first graph is a graph with a first variable on an x-axis, a second variable on a y-axis, and a third variable shown by color gradation of points on an xy plane,
wherein the x-axis and the y-axis are orthogonal to each other in the first graph,
wherein in the first graph, an X-ray diffraction spectrum is shown using a relation between the first variable and the third variable, the first variable corresponds to 2θ, and the third variable corresponds to an intensity of the spectrum, and
wherein the second variable corresponds to an ordinal number indicating how many times the X-ray diffraction spectrum has been measured.

19. The battery evaluation system according to claim 16,
wherein the measurement of the waveform such as the spectrum is X-ray diffraction spectrum measurement,
wherein in the first graph, a plurality of X-ray diffraction spectra with 2θ on an x-axis and a spectrum intensity on a y-axis are arranged in order of measurement with an offset provided in a direction of the y-axis, and
wherein the x-axis and the y-axis are orthogonal to each other in the first graph.

20. The battery evaluation system according to claim 19,
wherein the second graph is a graph with the voltage on the x-axis and elapsed time from a start of the measurement, capacity of the secondary battery, or capacity normalized with weight or volume of a positive electrode active material on the y-axis,
wherein the x-axis and the y-axis are orthogonal to each other in the second graph, and
wherein the first graph and the second graph are arranged side by side in a direction of the x-axis so that the direction of the y-axis of the first graph and a direction of the y-axis of the second graph are the same on a display portion.
